(19) United States
(12) Patent Application Publication
(10) Pub. No.: US 2013/0042912 A1
(43) Pub. Date: Feb. 21, 2013

(54) SOLDER BONDED BODY, METHOD OF PRODUCING SOLDER BONDED BODY, ELEMENT, PHOTOVOLTAIC CELL, METHOD OF PRODUCING ELEMENT AND METHOD OF PRODUCING PHOTOVOLTAIC CELL

(71) Applicants: Yoshiaki KURIHARA, Tsukuba-shi (JP); Masato Yoshida, Tsukuba-shi (JP); Takeshi Nojiri, Tsukuba-shi (JP); Shuichiro Adachi, Tsukuba-shi (JP); Takashiko Kato, Hitachi-shi (JP); Yasushi Kurata, Tsukuba-shi (JP)

(72) Inventors: Yoshiaki KURIHARA, Tsukuba-shi (JP); Masato Yoshida, Tsukuba-shi (JP); Takeshi Nojiri, Tsukuba-shi (JP); Shuichiro Adachi, Tsukuba-shi (JP); Takashiko Kato, Hitachi-shi (JP); Yasushi Kurata, Tsukuba-shi (JP)

(73) Assignee: HITACHI CHEMICAL COMPANY, LTD.

(21) Appl. No.: 13/572,475

(22) Filed: Aug. 10, 2012

Related U.S. Application Data
(60) Provisional application No. 61/522,830, filed on Aug. 12, 2011.

(30) Foreign Application Priority Data
Aug. 12, 2011 (JP) 2011-176982
Nov. 30, 2011 (JP) 2011-263043

(51) Int. Cl. H01L 31/0224; H01L 23/485; B32B 17/06; B32B 18/00; B23K 1/20; B32B 15/04

(52) U.S. Cl. 136/256; 228/256; 428/457; 428/469; 428/433; 428/450; 257/762; 257/E23.019

(57) ABSTRACT

The solder bonded body according to the present invention contains: an oxide body to be bonded having an oxide layer on the surface thereof; and a solder layer bonded to the oxide layer, which the solder layer is formed by an alloy containing at least two metals selected from the group consisting of tin, copper, silver, bismuth, lead, aluminum, titanium and silicon and having a melting point of lower than 450° C. and has a zinc content of 1% by mass or less.

### CROSS-REFERENCE TO RELATED APPLICATIONS

This application claims priority under 35 U.S.C. 119(e) form Provisional U.S. Patent Application No. 61/522,830, filed Aug. 12, 2011, and Japanese Patent Applications Nos. 2011-176982 filed Aug. 12, 2011 and 2011-263043 filed Nov. 30, 2011, the disclosure of which is incorporated by reference herein.

### BACKGROUND OF THE INVENTION

1. Field of the Invention

The present invention relates to a solder bonded body, a method of producing the solder bonded body, an element, a photovoltaic cell, a method of producing the element and a method of producing the photovoltaic cell.

2. Description of the Related Art

Generally, solders are broadly classified as lead-containing solders and lead-free solders. In general, it is thought that, when a solder is brought into contact with a body to be bonded at a temperature of not lower than the melting point of the solder, metal atoms are diffused between the solder and the body to be bonded to form an alloy at the interface, thereby bonding the solder with the body to be bonded. However, in cases where the surfaces of the solder and body to be bonded are covered with an oxide of, for example, a surface oxide film used for the purposes of preventing natural oxidation in the air and providing surface protection, so-called “solder wettability” is poor and the solder and the body to be bonded do not come into direct contact with each other, so that diffusion of metal atoms does not occur, making it difficult to achieve bonding between the solder and the body to be bonded.

In order to chemically remove this surface oxide film, a flux is employed. A flux has an effect of preventing surface oxidation of the solder and the body to be bonded associated with heating at the time of soldering, as well as an effect of improving the solder wettability by reducing the surface tension of molten solder. However, a flux residue, a residue of a halogen-based flux or the like, having residual activity, promotes the corrosion of the solder and the body to be bonded; therefore, it is required to remove such flux residues by washing after bonding treatment of the solder and the body to be bonded.

Examples of a method of bonding a solder and a body to be bonded including physical removal of this surface oxide film include a friction soldering method and an ultrasonic soldering method (see, for example, Japanese Patent No. 3205423 and Japanese Patent Application Laid-Open (JP-A) No. H9-216052). The friction soldering method is a soldering technique in which, while keeping a molten solder in contact with a surface oxide film of a metal body to be bonded, the surface oxide film is ground away with mechanical friction to bring the solder and the metal body to be bonded into direct contact, thereby allowing diffusion of metal atoms to bond the solder with the metal body to be bonded. Further, the ultrasonic soldering method is also a soldering technique in which, while keeping a molten solder in contact with a surface oxide film of a metal body to be bonded, the solder and the metal body to be bonded are brought into direct contact by detaching and removing the surface oxide film through utilization of the cavitation generated by ultrasonic vibration, thereby allowing diffusion of metal atoms to bond the solder with the metal body to be bonded. In these soldering methods, soldering can be achieved without using a flux; however, it is required to use an apparatus specific to for the respective methods.

Therefore, a solder which can be bonded to an inorganic non-metal compound such as a glass or a ceramic or to an inorganic metal compound has been investigated (see, for example, Japanese Patent No. 3664308). This solder binds with an inorganic non-metal compound such as a glass or a ceramic and to an inorganic metal compound by a chemical bond mediated by oxygen; therefore, it is required that at least the surfaces of the inorganic non-metal compound and the inorganic metal compound be covered with an oxide. Further, this solder requires the above-described ultrasonic vibration at the time of soldering.

Meanwhile, as a method of bonding a solder to an inorganic non-metal compound such as a glass or a ceramic or to an inorganic metal compound, a method is known in which the surfaces of the inorganic non-metal compound and the inorganic metal compound are coated in advance with, for example, silver, palladium, copper or a mixture thereof by vacuum deposition, electroless plating, baking or the like. In this method, however, the above-described surface-coating process needs to be performed prior to bonding a solder, and in cases where the metal to be coated is easily corroded by the solder, it is required to strictly control the selection of applicable solder and the soldering conditions.

Incidentally, a photovoltaic cell is generally provided with a surface electrode, and in cases where the surface electrode is made of copper or the like, an oxide film is generated on the surface. Therefore, when an attempt is made to bond the surface electrode with a wiring member such as a tab wire with a solder, the oxide film on the surface electrode may cause the above-described problems, resulting in an increase in the wiring resistance and contact resistance of the surface electrode. This leads to voltage loss, which is relevant to conversion efficiency.

Usually, a surface electrode of a photovoltaic cell is formed in the following manner. That is, a surface electrode is formed by applying a conductive composition by screen printing or the like on an n-type semiconductor layer, which is formed by thermally diffusing phosphorus or the like at a high temperature on the light-receiving surface side of a p-type silicon substrate, and then sintering the resultant at 800 to 900° C. This conductive composition forming the surface electrode contains, for example, a conductive metal powder, a glass particle and a variety of additives.

As the above-described conductive metal powder, silver powder is generally used; however, for a variety of reasons, the use of metal powder other than silver powder has been investigated. For example, there is disclosed a conductive composition containing silver and aluminum from which an electrode for a photovoltaic cell can be formed (see, for example, JP-A No. 2006-313744). Further, there is also disclosed a composition for electrode formation which contains metal nanoparticles containing silver and metal particles other than silver, such as copper (see, for example, JP-A No. 2008-226816).

Silver generally used in the formation of an electrode is a noble metal and thus from the viewpoint of resource issues as well as the high cost of the metal itself, there is a demand for a proposal of a paste material alternative to a silver-containing conductive composition (silver containing paste). An example of a promising material alternative to silver is copper used in semiconductor wiring materials. Copper is abundant as a resource and the price of the metal itself is also inexpensive at about a hundredth of silver. However, copper is a material which is easily oxidized at a high temperature of 200° C. or higher; therefore, for example, in the composition for electrode formation disclosed in JP-A No. 2008-226816, in cases where the composition contains copper as a conductive metal, in order to sinter the composition to form an electrode, a special process of performing sinter under a nitrogen atmosphere or the like is required.

### SUMMARY OF THE INVENTION

The first embodiment of the present invention is a solder bonded body, including: an oxide body to be bonded having an oxide layer on a surface thereof; and a solder layer bonded to the oxide layer, the solder layer having a zinc content of 1% by mass or less and being formed from an alloy containing at least two metals selected from the group consisting of tin, copper, silver, bismuth, lead, aluminum, titanium and silicon and having a melting point of lower than 450° C.

It is preferred that the above-described solder layer has an indium content of 1% by mass or less. Further, it is also preferred that the above-described solder layer be bonded at a temperature of from the solidus temperature to the liquidus temperature thereof and that the difference between the above-described liquidus temperature and solidus temperature be 2° C. or more.

It is preferred that the above-described oxide body to be bonded be at least one selected from the group consisting of oxides, metals covered with an oxide layer, glasses and oxide ceramics.

The second embodiment of the present invention is a method of producing the above-described solder bonded body, the method including: contacting with a solder layer to an oxide body to be bonded by bringing a solder material, which has a zinc content of 1% by mass or less and is formed from an alloy containing at least two metals selected from the group consisting of tin, copper, silver, bismuth, lead, aluminum, titanium and silicon and having a melting point of lower than 450° C.; and subjecting the resultant to a heat treatment at a temperature of from the solidus temperature to the liquidus temperature of the solder material.

In the above-described solder material used in the above-described method of producing the solder bonded body, it is preferred that the indium content be 1% by mass or less and that the difference between the above-described liquidus temperature and solidus temperature be 2° C. or more

It is preferred that the above-described temperature of from the solidus temperature to the liquidus temperature be one at which a ratio of the liquid phase in the whole solder layer is from 30% by mass to less than 100% by mass.

It is preferred that the above-described oxide body to be bonded used in the above-described method of producing the solder bonded body be at least one selected from the group consisting of oxides, metals covered with an oxide layer, glasses and oxide ceramics.

It is preferred that the method of producing the solder bonded body according to the present invention include no ultrasonic bonding process.

The third embodiment of the present invention is an element, including: a semiconductor substrate; an electrode provided on the semiconductor substrate, the electrode containing phosphorus and copper and having an oxide layer on a surface thereof; and a solder layer provided on the oxide layer, the solder layer being bonded at a temperature of from a solidus temperature to a liquidus temperature of the solder layer.

In the third embodiment of the present invention, it is preferred that the above-described temperature of from the solidus temperature to the liquidus temperature be higher than the solidus temperature and lower than the liquidus temperature.

In the third embodiment of the present invention, it is preferred that the above-described temperature of from the solidus temperature to the liquidus temperature be one at which the ratio of the liquid phase in the whole solder layer is from 30% by mass to less than 100% by mass.

It is preferred that the above-described electrode further contain tin.

The fourth embodiment of the present invention is an element, including a semiconductor substrate; an electrode provided on the semiconductor substrate, the electrode containing phosphorus and copper and having an oxide layer on a surface thereof; and a solder layer provided on said oxide layer, the solder layer having a difference between a liquidus temperature and a solidus temperature of 2° C. or more.

The fifth embodiment of the present invention is an element, including a semiconductor substrate; an electrode provided on the semiconductor substrate, the electrode containing phosphorus and copper and having an oxide layer on a surface thereof; and a solder layer bonded to the oxide layer.

It is preferred that the above-described element be an element for a photovoltaic cell in which the above-described semiconductor substrate has an impurity diffusion layer and is pn-joined and the above-described electrode is provided on the impurity diffusion layer.

The sixth embodiment of the present invention is a photovoltaic cell which has the above-described element for a photovoltaic cell and a wiring member which is provided on the oxide layer of the surface of the electrode in the above-described element for a photovoltaic cell and which is connected with a solder layer.

The seventh embodiment of the present invention is a method producing an element, the method including: preparing a substrate which has a semiconductor substrate and an electrode provided on the semiconductor substrate, the electrode containing phosphorus and copper and having an oxide layer on a surface thereof; and bonding a solder layer on the oxide layer by performing a heat treatment at a temperature of from a solidus temperature to a liquidus temperature of the solder layer.

The above-described method of producing an element is preferably a method of producing an element for a photovoltaic cell in which the above-described semiconductor substrate has an impurity diffusion layer and is pn-joined and the above-described electrode is provided on the impurity diffusion layer.

The eighth embodiment of the present invention is a method of producing a photovoltaic cell, the method including: preparing a photovoltaic cell substrate having a semiconductor substrate having an impurity diffusion layer to which it is pn-joined and an electrode provided on the impurity diffusion layer, the electrode containing phosphorus and copper and having an oxide layer on a surface thereof and bonding a wiring member on the oxide layer with a solder layer by subjecting the solder layer to a heat treatment at a temperature of from a solidus temperature to a liquidus temperature thereof.

### BRIEF DESCRIPTION OF THE DRAWINGS

FIG. 1 shows a cooling curve of a solder material X.

FIG. 2 is a cross-sectional view of the photovoltaic cell element according to the present invention.

FIG. 3 is a plan view showing the light-receiving surface side of the photovoltaic cell element according to the present invention.

FIG. 4 is a plan view showing the back surface side of the photovoltaic cell element according to the present invention.

FIG. 5A shows a back contact-type photovoltaic cell as an example of the photovoltaic cell element according to the present invention.

FIG. 5B is a plan view of a back contact-type photovoltaic cell as an example of the photovoltaic cell element according to the present invention.

### DETAILED DESCRIPTION OF THE INVENTION

The embodiments of the present invention will now be described in detail.

It is noted here that those ranges that are stated herein with “to” denote a range which includes the numerical values stated before and after “to” as the minimum and maximum values, respectively. In addition, the term “process” used herein encompasses not only an independent process but also a process which cannot be clearly distinguished from other processes, as long as its expected effect of the process is attained. Moreover, in the present specification, when reference is made to the amount of a component in a composition, in cases where the composition contains plural substances corresponding to the component, the indicated amount means the total amount of the plural substances present in the composition unless otherwise specified.

<Solder Bonded Body>

The solder bonded body according to the present invention has an oxide body to be bonded having an oxide layer on the surface thereof and a solder layer bonded to the above-described oxide layer. The above-described solder layer is formed by an alloy which contains at least two metals selected from the group consisting of tin, copper, silver, bismuth, lead, aluminum, titanium and silicon and has a melting point of lower than 450° C., in which the zinc content of the solder layer is 1% by mass or less.

As described in the foregoing, in cases where a flux is used in order to chemically remove the surface oxide film of a body to be bonded, a flux residue may promote corrosion of the body to be bonded. Therefore, it is required to completely remove the flux by washing and there is thus a demand for a method of soldering without using a flux. However, it is also important that a conventional soldering process may be applied with as little modification as possible without requiring a special soldering apparatus such as a mechanical friction device or an ultrasonic vibration device.

According to the present invention, a solder bonded body in which a solder layer is bonded at least on an oxide body to be bonded without using a flux and a method of producing the solder bonded body may be provided.

Further, according to the present invention, an element in which a solder layer is bonded to an electrode with excellent bonding property, in which electrode oxidation of copper during sinter is inhibited and a low resistivity is attained; a method of producing the element; a photovoltaic cell; and a method of producing the photovoltaic cell may be provided.

In the above-described solder bonded body, a solder material is directly bonded with the oxide layer of the oxide body to be bonded to form the solder layer. The expression “directly bonded” as used herein means that the oxide layer remains and is not removed, and the solder layer is bonded to the surface of the oxide layer. Further, this “bonding” may be achieved by any mechanical bonding between the oxide body to be bonded and the solder layer, and the metal atoms constituting the solder material do not have to be diffused in the oxide body to be bonded as in the case of normal soldering.

Specifically, the term “bond” means that the tensile bond strength between the oxide body to be bonded and the solder layer in the solder bonded body is 1.5 N/φ1.8 mm or larger and the tensile bond strength is preferably 3 N/φ1.8 mm or larger. Here, the tensile bond strength is measured in accordance with JIS H 8504 (Methods of Adhesion Test for Metallic Coatings) using a tensile tester (manufactured by Quad Group Inc.: thin-film adhesion strength measuring apparatus ROMULUS) and a stud-pin having a φ1.8-mm bonding surface (manufactured by Quad Group Inc.: φ1.8-mm copper stud-pin).

The above-described solder bonded body is formed by, for example, bringing a solder material into contact with an oxide body to be bonded and subjecting the solder material to a heat treatment at a temperature of from a solidus temperature to a liquidus temperature thereof to directly bond a solder layer on the surface of the oxide body to be bonded. The reason why such a solder bonded body is obtained is not clear; however, it may be thought as follows.

A solder material is, at a temperature between its solidus temperature and its liquidus temperature, in such a condition that a liquid phase and a solid phase may coexist. When an attempt is made to bond a solder material at a temperature higher than its liquidus temperature, that is, in a condition where the solder material is entirely in a liquid phase, the solder material in liquid phase condition is repelled by the surface tension, so that it is not bonded to the surface of an oxide body to be bonded surface. On the other hand, in a condition where a liquid phase solder material and a solid phase solder material coexist, it is thought that the presence of the solid phase solder material reduces the surface tension of the liquid phase solder material to inhibit the repelling of the solder material and the liquid phase solder material improves the wettability of the solder material as a whole, so that a solder layer is favorably bonded to the surface of an oxide body to be bonded.

In the above-described solder bonded body, from the viewpoint of attaining excellent bonding property and productivity of the solder bonded body, it is preferred that the solder layer be bonded to the oxide body to be bonded at a temperature of from the solidus temperature to the liquidus temperature thereof. More preferably, the solder layer is bonded to the oxide body to be bonded at a temperature which is not lower than the solidus temperature but lower than the liquidus temperature or at a temperature which is higher than the solidus temperature but not higher than the liquidus temperature. Still more preferably, the solder layer is bonded to the oxide body to be bonded at a temperature which is higher than the solidus temperature and lower than the liquidus temperature.

The solder layer in the above-described solder bonded body may also be further bonded with a wiring member, an electronic circuit element and/or the like as required. That is, the oxide body to be bonded may also be bonded with a wiring member, an electronic circuit element and/or the like via the solder layer. By bonding the above-described solder layer with a wiring member, an electronic circuit element and the like, the oxide body to be bonded may be connected mechanically and electrically with the wiring member, the electronic circuit element and the like.

Since the oxide body to be bonded and the solder layer are connected both mechanically electrically, the above-described solder bonded body may constitute a part of, for example, an electronic circuit board and a semiconductor substrate in which a ceramic substrate or a glass substrate is used; a MEMS element; a flat-panel display element having an oxide conductive film such as an ITO film or an IZO film as an electrode; a brazing member of metal-glass-oxide ceramic-nonoxide ceramic; an electric wiring; and an oxide wiring.

[Solder Layer]

From the viewpoint of further improving the bonding property and attaining more appropriate material cost, the solder material constituting the above-described solder layer is formed by an alloy which contains at least two metals selected from the group consisting of tin, copper, silver, bismuth, lead, aluminum, titanium and silicon and has a melting point of lower than 450° C. Generally, solder materials having a melting point of higher than 450° C. are called “brazing material”. The use of such a brazing material having a high-melting-point in an electronic circuit board or the like requires high-temperature heating for bonding and this may damage the circuit or the like; therefore, such use of a brazing material having a high-melting-point is not preferred.

The solder material constituting the above-described solder layer is preferably an alloy which contains at least two metals selected from the group consisting of tin, copper, silver, bismuth, lead, aluminum, titanium and silicon and has a melting point of from 96° C. to 327° C., and more preferably an alloy which contains tin and at least one metal selected from the group consisting of copper, silver, bismuth, lead, aluminum, titanium and silicon and has a melting point of from 96° C. to 232° C.

Further, in the above-described solder material, from the viewpoint of the wettability and the adhesion with the oxide body to be bonded, the zinc content is 1% by mass or less, preferably 0.5% by mass or less, and more preferably 0.1% by mass or less. The above-described solder material may contain zinc as long as the zinc content is 1% by mass or less. By allowing the above-described solder material to contain zinc, it is thought that zinc atoms and oxygen atoms of the oxide present on the surface of the oxide body to be bonded are bound together, improving the adhesion with the oxide body to be bonded. However, when the zinc content is higher than 1% by mass, the wettability with the oxide body to be bonded may be impaired in some cases.

Further, the above-described solder material may also be a lead-containing solder material or a lead-free solder material. Specific examples of the lead-containing solder material include Sn—Pb, Sn—Pb—Bi and Sn—Pb—Ag. Examples of the lead-free solder material include Sn—Ag—Cu, Sn—Ag, Sn—Cu and Bi—Sn.

Further, from the viewpoint of countermeasure for environmental problems and the like, it is also preferred that the above-described solder material be a solder containing substantially no lead. Here, the expression “containing substantially no lead” means that the lead content is 0.1% by mass or less, and preferably 0.05% by mass or less.

The above-described solder material may also further contain indium. Indium by itself has bonding property for oxide body to be bonded and is capable of lowering the melting point of a solder material when contained therein. However, since indium is an expensive material, the use thereof may be restricted. Further, it is known that, when a solder material contains indium, the durability of a solder layer formed therefrom is deteriorated; therefore, such a solder material may not be suitable for an application where long-term reliability of solder connection is demanded. From the viewpoint of the long-term reliability of solder connection, the content of indium in the above-described solder material is preferably 1% by mass or less, more preferably 0.5% by mass or less, and still more preferably 0.1% by mass or less.

Further, the above-described solder material may also contain, as required, other metal atom(s). Such other metal atom is not particularly restricted and may be selected as appropriate in accordance with the purpose thereof. Specific examples of other metal atom include manganese (Mn), antimony (Sb), potassium (K), sodium (Na), lithium (Li), barium (Ba), strontium (Sr), calcium (Ca), magnesium (Mg), beryllium (Be), cadmium (Cd), thallium (Tl), vanadium (V), zirconium (Zr), tungsten (W), molybdenum (Mo), cobalt (Co), nickel (Ni), gold (Au), chromium (Cr), iron (Fe), gallium (Ga), germanium (Ge), rhodium (Rh), iridium (Ir), yttrium (Y) and lanthanoids. Further, in cases where the above-described solder material contains other metal atoms(s), the content thereof may be selected as appropriate in accordance with the purpose thereof. For example, the content of other metal atom(s) in the above-described solder material may be 1% by mass or less, and from the viewpoint of the melting point and the adhesion with the oxide body to be bonded, it is preferably 0.5% by mass or less, and more preferably 0.1% by mass or less.

Further, in the above-described solder material, the difference between the liquidus temperature and the solidus temperature is preferably 1° C. or more, and more preferably from 1° C. to 300° C. Moreover, from the viewpoint of the workability, the above-described difference is preferably 2° C. or more, more preferably from 2° C. to 100° C., and still more preferably from 5° C. to 100° C. When the difference between the liquidus temperature and the solidus temperature is in the above-described range, the temperature at the time of bonding is easily controlled and excellent workability of the resulting solder bond is attained.

The liquidus temperature and the solidus temperature of the above-described solder material may be verified by examining a cooling curve obtained as a result of measuring the temperature of the solder material when the solder material in a molten state (liquid phase condition) is cooled. The liquidus temperature and the solidus temperature may be determined by a tangent line method based on the thus obtained cooling curve.

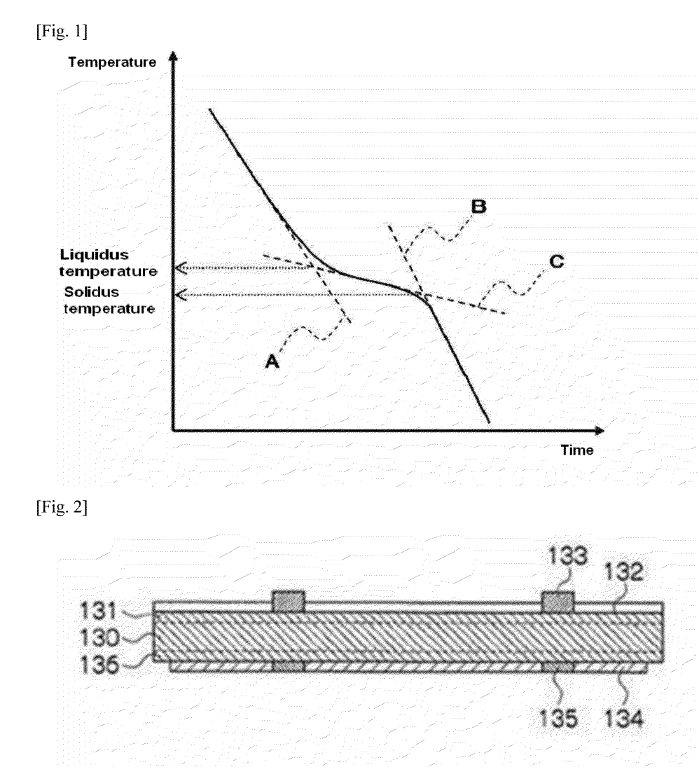

For example, the liquidus temperature and the solidus temperature of a solder material X forming the cooling curve shown in FIG. 1 may be determined as follows.

From a cooling curve obtained by cooling the solder material X in a liquid phase state, a first line A, which is extended from a linear region appearing when the solder material X is cooled in a liquid phase state (a region where the slope of the cooling curve is constant; the same applies hereinafter), a second line B, which is extended from a linear region appearing when the solder material X is cooled in a solid phase state, and a third line C, which is extended from a linear region existing between the linear region used to draw the first line A and the linear region used to draw the second line B, are obtained.

In this case, the intersection between the first line A and the third line C is defined as the liquidus temperature.

The intersection between the second line B and the third line C is defined as the solidus temperature.

It is noted here that the cooling curve of a solder material may be obtained by a method by which the change in the temperature of the solder material may be measured over time, such as by using a recorder connected with a thermocouple.

Further, the above-described liquidus temperature and solidus temperature of a solder material may be controlled to within a desired range by appropriately selecting the type and mixing ratio of the metals constituting the solder material.

As the above-described solder material, a commercially available product having a desired composition may be employed, or the above-described solder material may be one which is produced by a method normally employed. Specifically, a desired solder material may be produced by mixing the respective materials constituting the solder material at a prescribed ratio and melting and then rapidly cooling the resultant.

The above-described solder layer is formed by bonding the above-described solder material on an oxide body to be bonded. The details of the method of forming the solder layer will be described later. The above-described solder layer may also contain a flux. As the flux, one which has relatively weak activity is preferred. Specific examples of such flux include rosin-based, RMA-based and R-type fluxes.

It is preferred, however, that the above-described solder layer contain substantially no flux. By allowing the above-described solder material to contain substantially no flux, when bonding the above-described solder layer onto the above-described oxide body to be bonded, the process of drying the solvent component contained in the above-described flux may be omitted. In addition, the flux washing process after bonding the above-described solder layer onto the above-described oxide body to be bonded may also be omitted. Furthermore, the corrosive reaction of the above-described flux against the oxide body to be bonded may be inhibited. Here, the expression “contain substantially no flux” means that the total amount of flux contained in the solder material is 2% by mass or less, and preferably 1% by mass or less.

[Oxide Body to be Bonded]

The oxide body to be bonded according to the present invention is not particularly restricted as long as it has an oxide layer at least on the surface thereof. For example, the above-described oxide body to be bonded is selected from the group consisting of oxides, metals covered with an oxide layer, glasses and oxide ceramics.

Examples of the above-described oxides include indium tin oxide (ITO), silicon dioxide, chromium oxide and boron oxide.

Examples of metal species in the above-described metals covered with an oxide layer include copper, iron, titanium, aluminum, silver and stainless steel.

The above-described glasses are not particularly restricted and examples thereof include alkali-free glasses, quartz glasses, low-alkali glasses and alkali glasses.

Examples of the above-described oxide ceramics include alumina ceramics, zirconia ceramics, magnesia ceramics and calcia ceramics.

Here, the reason why the above-described solder layer according to the present invention is formed such that it is bonded to the oxide body to be bonded is thought to be because repelling of the solder material against the oxide layer is inhibited and the wettability of the solder material as a whole is improved. Accordingly, the solder layer-forming region on the oxide body to be bonded does not have to be entirely covered with an oxide, as long as an oxide layer is formed on at least a portion of the solder layer-forming region.

Whether or not the above-described oxide body to be bonded has an oxide layer on the surface thereof may be verified by energy dispersive X-ray analysis (EDX).

<Method of Producing Solder Bonded Body>

The method of producing a solder bonded body according to the present invention include the process of bonding a solder layer to the above-described oxide body to be bonded by bringing above-described solder material into contact with the above-described oxide body to be bonded and subjecting the resultant to a heat treatment at a temperature of from the solidus temperature to the liquidus temperature of the above-described solder material. The method of producing a solder bonded body according to the present invention may also include other process(s) as required. By heat-treating the solder material on the oxide body to be bonded in a specific temperature range, the solder layer may be bonded onto the oxide body to be bonded. The details of the above-described oxide body to be bonded and solder material are as described in the above.

Here, the expression “a temperature of from the solidus temperature to the liquidus temperature” is a temperature between the solidus temperature and the liquidus temperature, including the solidus temperature and the liquidus temperature. From the viewpoint of bonding the solder layer in a condition where liquid phase and solid phase coexist, the temperature in the above-described bonding process is preferably a temperature which is not lower than the solidus temperature but lower than the liquidus temperature or a temperature which is higher than the solidus temperature but not higher than the liquidus temperature, and more preferably a temperature which is higher than the solidus temperature and lower than the liquidus temperature.

Further, from the viewpoint of further improving the bonding property, it is preferred to adjust the ratio of the liquid phase and the solid phase in the solder layer at the time of bonding. Specifically, the bonding is performed at a temperature at which the ratio of the liquid phase in the whole solder layer becomes preferably from 30% by mass to less than 100% by mass, more preferably from 35% by mass to 99% by mass, and still more preferably from 40% by mass to 98% by mass.

Here, the ratio of the liquid phase at the time of the solder bonding may be determined from an equilibrium diagram of the solder composition used.

The method of the heat treatment is not particularly restricted and a conventionally known method may be employed. Examples thereof include a method in which an oxide body to be bonded is heated using a hot plate or the like and a solder material is placed on the thus heated oxide body to be bonded and heat-treated using a soldering iron whose temperature is set to be the same as that of the hot plate, while controlling the temperature of the solder material; and a method in which a solder placed on an oxide body to be bonded is passed through a reflow furnace having a constant temperature.

In the above-described bonding process, it is preferred that the bonding be performed while pressing the solder material against the oxide body to be bonded. As a result, the solid phase in the solder material is pressed against the above-described oxide body to be bonded, so that the bonding property is further improved. This pressing pressure may be set as appropriate and, for example, it is set preferably at 200 Pa to 5 MPa, and more preferably at 1 kPa to 2 MPa.

Further, in the bonding process, the time of the heat treatment is preferably 1 second or longer, more preferably 3 seconds or longer, and still more preferably 10 seconds or longer. By this, the solid phase in the solder material is further pressed against the above-described oxide body to be bonded, so that the bonding property of the resulting solder layer is improved.

Further, in the above-described solder bonded body, in cases where the solder layer is further bonded with a wiring member or the like as required, the wiring member or the like may be bonded to the solder layer while the solder layer is bonded to the oxide body to be bonded, or a wiring member or the like may be bonded to the solder layer after the solder layer is bonded to the oxide layer.

<Element>

The element according to the present invention contains a semiconductor substrate, an electrode provided on the above-described semiconductor substrate and a solder layer provided on the above-described electrode. Further, the above-described electrode contains phosphorus and copper and has an oxide layer on the surface thereof.

By allowing the above-described electrode to contain phosphorus and copper, an electrode having a low resistivity may be obtained. This is thought to be because phosphorus functions as a reducing agent for copper oxide and the oxidation resistance of copper is thus improved. It is speculated that oxidation of copper is thereby suppressed during sinter in the electrode preparation, resulting in formation of an electrode having a low resistivity. Here, although oxidation of copper during sinter is suppressed, oxide layers of phosphorus and copper are formed on the electrode surface.

Here, in cases where the solder layer is formed after removing the above-described oxide layer with a flux or the like, the above-described electrode may be corroded by the flux. Therefore, in the present invention, it is preferred that the above-described solder layer contain no flux. That is, in the present invention, the solder layer is formed on the oxide layer without removing the oxide layer by the flux or the like at all or without entirely removing the oxide layer. As a result, occurrence of defects due to electrode corrosion caused by a flux may be inhibited and the process of drying the solvent component contained in the above-described flux and the process of washing the flux may be omitted or simplified.

The above-described electrode and solder layer are bonded by bringing them into contact to press them against each other and subjecting the resultant to a heat treatment. This heat treatment is performed at a temperature of from the solidus temperature to the liquidus temperature of the above-described solder layer. By this, the solder layer is bonded with excellent adhesion on the oxide layer formed on the surface of the above-described electrode.

The constituting members of the element according to the present invention will now be described below.

[Semiconductor Substrate]

The type of the semiconductor substrate in the present invention is not particularly restricted as long as it is a semiconductor substrate which is used in a mode where an electrode is formed using the above-described electrode paste composition and a solder layer is formed on the electrode. Examples of such semiconductor substrate include silicon substrates having a pn junction that are used for the formation of a photovoltaic cell; silicon substrates that are used in semiconductor devices; and silicon carbide substrates that are used as base materials of light-emitting diodes.

[Electrode]

The electrode according to the present invention contains phosphorus and copper. From the viewpoint of the oxidation resistance and attaining a low resistivity, the phosphorus content is preferably from 4.5% by mass to 9% by mass, more preferably from 5.5% by mass to 8% by mass, and still more preferably from 6.5% by mass to 7.5% by mass, with respect to the total amount of copper and phosphorus. By controlling the phosphorus content at 9% by mass or less, a lower resistivity may be attained, and by controlling the phosphorus content at 4.5% by mass or more, superior oxidation resistance may be attained.

The electrode containing phosphorus and copper may be obtained by, for example, sintering an electrode paste composition containing phosphorus and copper. Examples of the above-described electrode paste composition include those which contain a glass particle, a phosphorus-containing copper alloy particle, a solvent and a resin. By having such a constitution, a glass layer which is an oxide is formed on the surface at the time of sinter, so that oxidation of copper is inhibited and an electrode having a low resistivity may be formed.

Further, it is preferred that the electrode further contain tin. In the above-described electrode paste composition, tin may be contained in the above-described phosphorus-containing copper alloy particle or may be contained as a tin-containing particle separately from the phosphorus-containing alloy particle.

The electrode paste composition used for the formation of the electrode will now be described in detail.

(Phosphorus-Containing Copper Alloy Particle)

The electrode paste composition according to the present invention contains at least one phosphorus-containing copper alloy particle.

From the viewpoint of the oxidation resistance and attaining a low resistivity, the phosphorus content in the phosphorus-containing copper alloy particle is preferably from 6% by mass to 8% by mass, more preferably from 6.3% by mass to 7.8% by mass, and still more preferably from 6.5% by mass to 7.5% by mass. By controlling the phosphorus content in the phosphorus-containing copper alloy particle at 8% by mass or less, a lower resistivity of the electrode and excellent productivity of the phosphorus-containing copper alloy particle may be attained. Further, by controlling the phosphorus content at 6% by mass or more, superior oxidation resistance may be attained.

As a phosphorus-containing copper alloy used in the above-described phosphorus-containing copper alloy particle, brazing materials called “phosphor-copper brazing material” (phosphorus concentration: usually about 7% by mass or less) are known. A phosphor-copper brazing material is also used as a copper-copper bonding agent. By using such phosphorus-containing copper alloy particle in the electrode paste composition according to the present invention, the reducing property of phosphorus against copper oxide may be utilized to form an electrode having excellent oxidation resistance and a low resistivity. Further, since low-temperature sinter of the electrode becomes possible, a process cost-reducing effect may be attained.

The above-described phosphorus-containing copper alloy particle is constituted by an alloy containing copper and phosphorus; however, the phosphorus-containing copper alloy particle may further contain other atom(s) as well. Examples of such other atom include Ag, Mn, Sb, Si, K, Na, Li, Ba, Sr, Ca, Mg, Be, Zn, Pb, Cd, Tl, V, Sn, Al, Zr, W, Mo, Ti, Co, Ni and Au.

The content of such atom(s) other than copper and phosphorus in the above-described phosphorus-containing copper alloy particle may be, for example, 3% by mass or less, and from the viewpoint of the oxidation resistance and attaining a low resistivity, it is preferably 1% by mass or less.

Further, in the present invention, the above-described phosphorus-containing copper alloy particle may be used individually, or two or more thereof may be used in combination.

The size of the above-described phosphorus-containing copper alloy particle is not particularly restricted; however, the particle size at which the cumulative weight from the smaller particle side reaches 50% (hereinafter, may be abbreviated as “D50%”) is preferably 0.4 μm to 10 μm, and more preferably 1 μm to 7 μm. By controlling the particle size at 0.4 μm or larger, the oxidation resistance is improved more effectively. Further, by controlling the particle size at 10 μm or smaller, the area of the phosphorus-containing copper alloy particles in contact with each other in the electrode is increased, so that the resistivity of the resulting electrode is reduced more effectively. Here, the size of the phosphorus-containing copper alloy particle is measured using a MICROTRAC particle size distribution measuring apparatus (manufactured by Nikkiso Co., Ltd.; model MT3300).

Further, the shape of the above-described phosphorus-containing copper alloy particle is not particularly restricted and it may assume any of, for example, a substantially spherical shape, a flat shape, a block shape, a plate shape and a squamous shape. From the viewpoint of the oxidation resistance and attaining a low resistivity, the shape of the above-described phosphorus-containing copper alloy is preferably a substantially spherical shape, a flat shape or a plate shape.

The content of the above-described phosphorus-containing copper alloy particle in the electrode paste composition according to the present invention or the total content of the phosphorus-containing copper alloy particle and the later-described silver particle in cases where the silver particle is contained may be, for example, 70% by mass to 94% by mass, and from the viewpoint of the oxidation resistance and attaining a low resistivity, it is preferably from 72% by mass to 90% by mass, and more preferably from 74% by mass to 88% by mass.

The phosphorus-containing copper alloy used for the above-described phosphorus-containing copper alloy particle may be produced by a method which is normally employed. Further, the phosphorus-containing copper alloy particle may also be prepared by a conventional metal powder preparation method using a phosphorus-containing copper alloy prepared to have a desired phosphorus content. For example, the phosphorus-containing copper alloy particle may be produced by a conventional method using a water atomization method. It is noted here that the details of the water atomization method are described in Handbook of Metal (Maruzen Co., Ltd., Publishing Dept.) and the like.

Specifically, a desired phosphorus-containing copper alloy particle may be produced by, for example, after dissolving a phosphorus-containing copper alloy and powderizing the resultant by nozzle atomization, drying and classifying the thus obtained powder. Further, by selecting the classification conditions as appropriate, a phosphorus-containing copper alloy particle having a desired particle size may be produced.

(Tin-Containing Particle)

It is preferred that the above-described electrode paste composition contain at least one tin-containing particle. By allowing the electrode paste composition to contain a tin-containing particle in addition to the phosphorus-containing copper alloy particle, an electrode having a low resistivity may be formed in the later-described sinter process.

The reason for this may be thought, for example, as follows. The phosphorus-containing copper alloy particle and the tin-containing particle react with each other in the sinter process to form an electrode composed of a Cu—Sn alloy phase and a Sn—P—O glass phase. Here, it is thought that, inside the thus formed electrode, the above-described Cu—Sn alloy phase forms a compact bulk body which functions as a conductive layer, thereby an electrode having a low resistivity may be formed. It is noted here that the term “compact bulk body” used herein means that aggregates of the Cu—Sn alloy phase are in close contact with each other, forming a three-dimensionally continuous structure.

Further, in cases where an electrode is formed on a silicon-containing substrate (hereinafter, may also be simply referred to as “silicon substrate”) using the above-described electrode paste composition, an electrode having a high adhesion with the silicon substrate may be formed and excellent ohmic contact may be attained between the electrode and the silicon substrate.

The reason for this may be thought, for example, as follows. The phosphorus-containing copper alloy particle and the tin-containing particle react with each other in the sinter process to form an electrode composed of a Cu—Sn alloy phase and a Sn—P—O glass phase. Since the above-described Cu—Sn alloy phase is a compact bulk body, the Sn—P—O glass phase is formed between the Cu—Sn alloy phase and the silicon substrate, and this may be thought to improve the adhesion between the Cu—Sn alloy phase and the silicon substrate. Further, it may be thought that the Sn—P—O glass phase functions as a barrier layer for preventing interdiffusion of copper and silicon, thereby excellent ohmic contact may be attained between the electrode formed by sinter and the silicon substrate. That is, it is thought that excellent ohmic contact may be exhibited while inhibiting the formation of a reaction phase (Cu₃Si), which is formed when a copper-containing electrode and silicon are heated in direct contact with each other, and maintaining the adhesion with the silicon substrate without impairing the semiconductor performance (such as pn junction characteristics).

The above-described tin-containing particle is not particularly restricted as long as it is a particle containing tin. Among such particles, the tin-containing particle is preferably at least one selected from tin particles and tin alloy particles, more preferably at least one selected from tin particles and tin alloy particles having a tin content of 1% by mass or more.

The tin purity in the tin particle is not particularly restricted. For example, the purity of tin particle may be 95% by mass or more, and it is preferably 97% by mass or more, and more preferably 99% by mass or more.

Further, the alloy type of the tin alloy particle is not particularly restricted as long as it is an alloy particle containing tin. Among such alloy particles, from the viewpoint of the melting point of the tin alloy particle and the reactivity with the phosphorus-containing copper alloy particle, the tin alloy particle has a tin content of preferably 1% by mass or more, more preferably 3% by mass or more, still more preferably 5% by mass or more, and particularly preferably 10% by mass or more.

Examples of the tin alloy particle include Sn—Ag-based alloys, Sn—Cu-based alloys, Sn—Ag—Cu-based alloys, Sn—Ag—Sb-based alloys, Sn—Ag—Sb—Zn-based alloys, Sn—Ag—Cu—Zn-based alloys, Sn—Ag—Cu—Sb-based alloys, Sn—Ag—Bi-based alloys, Sn—Bi-based alloys, Sn—Ag—Cu—Bi-based alloys, Sn—Ag—In—Bi-based alloys, Sn—Sb-based alloys, Sn—Bi—Cu-based alloys, Sn—Bi—Cu—Zn-based alloys, Sn—Bi—Zn-based alloys, Sn—Bi—Sb—Zn-based alloys, Sn—Zn-based alloys, Sn—In-based alloys, Sn—Zn—In-based alloys and Sn—Pb-based alloys.

Among the above-described tin alloy particles, tin alloy particles of Sn-3.5Ag, Sn-0.7Cu, Sn-3.2Ag-0.5Cu, Sn-4Ag-0.5Cu, Sn-2.5Ag-0.8Cu-0.5Sb, Sn-2Ag-7.5Bi, Sn-3Ag-5Bi, Sn-58Bi, Sn-3.5Ag-3In-0.5Bi, Sn-3Bi-8Zn, Sn-9Zn, Sn-52In, Sn-40Pb and the like have the same melting point (232° C.) or a lower melting point than that of Sn. Therefore, these tin alloy particles may be suitably employed because, by melting them in the initial stage of sinter, they may cover the surface of the phosphorus-containing copper alloy particle and uniformly react therewith. It is noted here that the notation of the tin alloy particle indicates that, for example, in the case of Sn-AX-BY-CZ, the tin alloy particle contains A % by mass of element X, B % by mass of element Y and C % by mass of element Z.

In the present invention, these tin-containing particles may be used individually, or two or more thereof may be used in combination.

The above-described tin-containing particle may further contain other atom(s) that is/are unavoidably mixed therein. Examples such atoms include Ag, Mn, Sb, Si, K, Na, Li, Ba, Sr, Ca, Mg, Be, Zn, Pb, Cd, Tl, V, Al, Zr, W, Mo, Ti, Co, Ni and Au.

Further, the content of such other atom(s) in the above-described tin-containing particle may be, for example, 3% by mass or less, and from the viewpoint of the melting point and the reactivity with the phosphorus-containing copper alloy particle, it is preferably 1% by mass or less.

The size of the above-described tin-containing particle is not particularly restricted; however, the D50% is preferably from 0.5 μm to 20 μm, more preferably from 1 μm to 15 μm, and still more preferably from 5 μm to 15 μm. By controlling the D50% at 0.5 μm or greater, the oxidation resistance of the tin-containing particle per se is improved. Further, by controlling the D50% at 20 μm or smaller, the area of the tin-containing particle in contact with the phosphorus-containing copper alloy particle is increased, so that the reaction with the phosphorus-containing copper alloy particle proceeds effectively.

The shape of the above-described tin-containing particle is not particularly restricted and it may be any of, for example, a substantially-spherical shape, a flat shape, a block shape, a plate shape and a squamous shape. From the viewpoint of the oxidation resistance and attaining a low resistivity, it is preferred that the shape of the above-described tin-containing particle is a shape of a substantially-spherical shape, a flat shape or a plate shape.

Further, the content of the tin-containing particle in the above-described electrode paste composition is not particularly restricted. However, taking the total content of the above-described phosphorus-containing copper alloy particle and the tin-containing particle as 100% by mass, the content of the tin-containing particle is preferably from 5% by mass to 70% by mass, more preferably from 7% by mass to 65% by mass, and still more preferably from 9% by mass to 60% by mass.

By controlling the content of the tin-containing particle at 5% by mass or more, the reaction with the phosphorus-containing copper alloy particle may take place more uniformly. Further, by controlling the content of the tin-containing particle at 70% by mass or less, a Cu—Sn alloy phase of a sufficient volume may be formed, so that the volume resistivity of the electrode is further reduced.

(Glass Particle)

The electrode paste composition according to the present invention contains at least one glass particle. By allowing the electrode paste composition to contain a glass particle, the adhesion between the electrode portion and a substrate at the time of sinter is improved. Further, for example, in cases where an electrode is formed on a silicon substrate having a silicon nitride film, which is an anti-reflection film, on the surface thereof, the above-described silicon nitride film is removed by so-called “fire-through” at an electrode-forming temperature and an ohmic contact is formed between the electrode and the silicon substrate.

The above-described glass particle is not particularly restricted as long as it is a glass particle normally used in the art which is capable of softening and melting at an electrode-forming temperature as well as oxidizing a silicon nitride film in contact to be silicon dioxide and removing the anti-reflection film by incorporating the resulting silicon dioxide.

From the viewpoint of the oxidation resistance and attaining an electrode having a low resistivity, the glass particle is preferably one which contains a glass having a glass softening point of 600° C. or less and a crystallization onset temperature of higher than 600° C. Here, the above-described glass softening point is measured by a conventional method using a thermal mechanical analyzer (TMA) and the above-described crystallization onset temperature is measured by a conventional method using a differential thermal-thermogravimetric analyzer (TG/DTA).

In general, the glass particle contained in an electrode paste composition may also be constituted by a lead-containing glass, because such lead-containing glass is capable of efficiently incorporating silicon dioxide. Examples of such lead-containing glass include those described in the specification of Japanese Patent No. 03050064 and the like and these lead-containing glasses may be suitably used also in the present invention.

Further, taking into consideration the effects on the environment, it is preferred to use a lead-free glass which contains substantially no lead. Examples of the lead-free glass include the one described in the paragraphs [0024] to [0025] of JP 2006-313744A and the one described in JP 2009-188281A, and it is also preferred that the lead-free glass be selected therefrom as appropriate for use.

Examples of glass component constituting the glass particle used in the electrode paste composition according to the present invention include silicon dioxide (SiO₂), phosphorus oxide (P₂O₅), aluminum oxide (Al₂O₃), boron oxide (B₂O₃), vanadium oxide (V₂O₅), potassium oxide (K₂O), bismuth oxide (Bi₂O₃), sodium oxide (Na₂O), lithium oxide (Li₂O), barium oxide (BaO), strontium oxide (SrO), calcium oxide (CaO), magnesium oxide (MgO), beryllium oxide (BeO), zinc oxide (ZnO), lead oxide (PbO), cadmium oxide (CdO), tin oxide (SnO), zirconium oxide (ZrO₂), tungsten oxide (WO₃), molybdenum oxide (MoO₃), lanthanum oxide (La₂O₃), niobium oxide (Nb₂O₅), tantalum oxide (Ta₂O₅), yttrium oxide (Y₂O₃), titanium oxide (TiO₂), germanium dioxide (GeO₂), tellurium oxide (TeO₂), lutetium oxide (Lu₂O₃), antimony oxide (Sb₂O₃), copper oxide (CuO), iron oxide (FeO), silver oxide (AgO) and manganese oxide (MnO).

Thereamong, it is preferred to use at least one selected from SiO₂, P₂O₅, Al₂O₃, B₂O₃, V₂O₅, Bi₂O₃, ZnO and PbO. A specific example of the glass component is one which contains SiO₂, PbO, B₂O₃, Bi₂O₃ and Al₂O₃. In cases where such a glass particle is employed, since the softening point is effectively lowered and the wettability with the phosphorus-containing copper alloy particle and the silver particle added as required is improved, sintering between the above-described particles in the sinter process progresses, so that an electrode having a low resistivity may be formed.

Meanwhile, from the viewpoint of attaining low contact resistivity of the resulting electrode, a glass particle containing diphosphorus pentaoxide (phosphate glass, P₂O₅-based glass particle) is preferred, and a glass particle which further contains divanadium pentoxide in addition to diphosphorus pentaoxide (P₂O₅—V₂O₅-base glass particle) is more preferred. By allowing the glass particle to further contain divanadium pentoxide, the oxidation resistance is further improved and the resistivity of the resulting electrode is further reduced. This may be thought to be attributed to, for example, that the softening point of the glass is lowered by further containing divanadium pentoxide. In cases where a diphosphorus pentaoxide-divanadium pentoxide-based glass particle (P₂O₅—V₂O₅-based glass particle) is used, the content of divanadium pentoxide is preferably 1% by mass or more, and more preferably from 1% by mass to 70% by mass, with respect to the total glass mass.

The size of the above-described glass particle is not particularly restricted; however, the D50% is preferably from 0.5 μm to 10 μm, and more preferably from 0.8 μm to 8 μm. By controlling the D50% at 0.5 μm or larger, the workability at the time of the preparation of the electrode paste composition is improved. Further, by controlling the D50% at 10 μm or smaller, the glass particle is uniformly dispersed in the electrode paste composition, so that fire-through may occur efficiently in the sinter process and the adhesion with the silicon substrate is also improved.

The content of the above-described glass particle is preferably from 0.1% by mass to 10% by mass, more preferably from 0.5% by mass to 8% by mass, and still more preferably from 1% by mass to 7% by mass, with respect to the total mass of the electrode paste composition. By controlling the content of the glass particle in the above-described range, oxidation resistance, low resistivity of the resulting electrode and low contact resistivity are attained more effectively.

(Solvent and Resin)

The electrode paste composition according to the present invention contains at least one solvent and at least one resin. By this, the liquid properties (such as viscosity and surface tension) of the electrode paste composition according to the present invention may be adjusted to the liquid properties that are required in accordance with the method of providing the electrode paste composition on the silicon substrate.

The above-described solvent is not particularly restricted. Examples thereof include hydrocarbon-based solvents such as hexane, cyclohexane and toluene; chlorinated hydrocarbon-based solvents such as dichloroethylene, dichloroethane and dichlorobenzene; cyclic ether-based solvents such as tetrahydrofuran, furan, tetrahydropyran, pyran, dioxane, 1,3-dioxolane and trioxane; amide-based solvents such as N,N-dimethylformamide and N,N-dimethylacetamide; sulfoxide-based solvents such as dimethyl sulfoxide and diethyl sulfoxide; ketone-based solvents such as acetone, methyl ethyl ketone, diethyl ketone and cyclohexanone; alcohol-based compounds such as ethanol, 2-propanol, 1-butanol and diacetone alcohol; polyhydric alcohol ester-based solvents such as 2,2,4-trimethyl-1,3-pentanediol monoacetate, 2,2,4-trimethyl-1,3-pentanediol monopropionate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate and diethylene glycol monobutyl ether acetate; polyhydric alcohol ether-based solvents such as butylcellosolve, diethylene glycol monobutyl ether and diethylene glycol diethyl ether; terpene-based solvents such as α-terpinene, α-terpineol, myrcene, allo-ocimene, limonene, dipentene, α-pinene, β-pinene, terpineol, carvone, ocimene and phellandrene; and mixtures thereof.

The above-described solvent in the present invention is, from the viewpoint of the coating properties and printing properties in the formation of the electrode paste composition on the silicon substrate, preferably at least one selected from polyhydric alcohol ester-based solvents, terpene-based solvents and polyhydric alcohol ether-based solvents, and more preferably at least one selected from polyhydric alcohol ester-based solvents and terpene-based solvents.

In the present invention, the above-described solvents may be used individually, or two or more thereof may be used in combination.

As the above-described resin, one which is normally used in the art may be employed without any particular restriction as long as it is thermally decomposable by sinter. Specific examples of such resin include cellulose-based resins such as methyl cellulose, ethyl cellulose, carboxymethyl cellulose and nitrocellulose; polyvinyl alcohols; polyvinylpyrrolidones; acrylic resins; vinyl acetate-acrylate copolymers; butyral resins such as polyvinyl butyral; alkyd resins such as phenol-modified alkyd resins and castor oil-fatty acid-modified alkyd resins; epoxy resins; phenol resins; and rosin ester resins.

The above-described resin in the present invention is, from the viewpoint of the elimination property thereof at the time of sinter, preferably at least one selected from cellulose-based resins and acrylic resins, and more preferably one selected from cellulose-based resins.

In the present invention, the above-described resins may be used individually, or two or more thereof may be used in combination.

Further, the weight average molecular weight of the above-described resin in the present invention is not particularly restricted. Still, the weight average molecular weight is preferably from 5,000 to 500,000, and more preferably 10,000 to 300,000. When the weight average molecular weight of the above-described resin is 5,000 or more, an increase in the viscosity of the electrode paste composition may be inhibited. This may be thought to be because, for example, steric repulsion at the time of adsorbing the resin to the phosphorus-containing copper alloy particle is efficiently exerted, whereby aggregation phenomenon of the particles is thus inhibited. Meanwhile, when the weight average molecular weight of the resin is 500,000 or less, the resin is inhibited to aggregate with each other in the solvent and as a result, phenomenon of increase in the viscosity of the electrode paste composition is inhibited. In addition, by controlling the weight average molecular weight of the resin at an appropriate level, an increase in the combustion temperature of the resin may be inhibited, and incomplete combustion of the resin at the time of sintering the electrode paste composition may be prevented, which inhibits to remain the resin as a foreign substance, so that an electrode having a low resistivity may be attained.

The above weight average molecular weight of the resin is the value obtained by measuring with gel permeation chromatography method and then reducing with standard polystyrene calibration curve.

In the electrode paste composition according to the present invention, the contents of the above-described solvent and resin may be selected as appropriate in accordance with the desired liquid properties and the respective types of the solvent and the resin that are used.

For example, the content of the resin is preferably from 0.01% by mass to 5% by mass, more preferably from 0.05% by mass to 4% by mass, still more preferably from 0.1% by mass to 3% by mass, and yet still more preferably from 0.15% by mass to 2.5% by mass, with respect to the total mass of the electrode paste composition.

Further, the total content of the solvent and the resin is preferably from 3% by mass to 29.8% by mass, more preferably from 5% by mass to 25% by mass, and still more preferably from 7% by mass to 20% by mass, with respect to the total mass of the electrode paste composition.

By controlling the contents of the solvent and the resin in the above-described range, excellent suitability for providing the electrode paste composition on the silicon substrate may be attained and an electrode having desired width and height may be formed more easily.

(Silver Particle)

It is preferred that the electrode paste composition according to the present invention further contain at least one silver particle. By allowing the electrode paste composition to contain a silver particle, the oxidation resistance is further improved and the resistivity as a resulting electrode is further reduced. Further, in cases where the electrode paste composition is used in a photovoltaic cell module, a solder connectivity-improving effect is also attained. The reason for this may be thought, for example, as follows.

In general, in a temperature range of from 600° C. to 900° C., which is an electrode-forming temperature range, a small amount of a solid solution of silver in copper and a small amount of a solid solution of copper in silver are generated and a layer of copper-silver solid solution (solid solution region) is formed at the interface between copper and silver. In cases where a mixture of the phosphorus-containing copper alloy particle and the silver particle is heated to a high temperature and then slowly cooled to room temperature, it is thought that such solid solution region is not generated; however, when forming an electrode, since cooling is carried out in a few seconds from a high temperature region to room temperature, it is thought that the layer of the solid solution at a high temperature would cover the surfaces of the silver particle and the phosphorus-containing copper alloy particle as a non-equilibrium solid solution phase or as a eutectic structure of copper and silver. Such a copper-silver solid solution layer may be thought to contribute to the oxidation resistance of the phosphorus-containing copper alloy particle at an electrode-forming temperature.

The copper-silver solid solution layer starts to be formed at a temperature of from 300° C. to 500° C. or higher. Therefore, it may be thought that, by using the silver particle in combination of a phosphorus-containing copper alloy particle whose peak temperature of the exothermic peak showing the maximum area in simultaneous differential thermal-thermogravimetric measurement is 280° C. or higher, the oxidation resistance of the phosphorus-containing copper alloy particle may be improved more effectively, so that the resistivity of the resulting electrode is further reduced.

The silver constituting the above-described silver particle may contain other atom(s) that is/are unavoidably mixed therein. Examples such atoms include Sb, Si, K, Na, Li, Ba, Sr, Ca, Mg, Be, Zn, Pb, Cd, Tl, V, Sn, Al, Zr, W, Mo, Ti, Co, Ni and Au.

Further, the content of such other atom(s) in the above-described silver particle may be, for example, 3% by mass or less, and from the viewpoint of the melting point and attaining an electrode having a low reactivity, it is preferably 1% by mass or less.

The size of the silver particle in the present invention is not particularly restricted; however, the D50% is preferably from 0.4 μm to 10 μm, and more preferably from 1 μm to 7 μm. By controlling the D50% at 0.4 μm or larger, the oxidation resistance is improved more effectively. Further, by controlling the D50% at 10 μm or smaller, the area where metal particles such as the silver particle and the phosphorus-containing copper alloy particle are in contact with each other in the electrode is increased, so that the resistivity of the resulting electrode is reduced more effectively.

In the electrode paste composition according to the present invention, the relationship between the particle size (D50%) of the above-described phosphorus-containing copper alloy particle and that of the above-described silver particle is not particularly restricted; however, it is preferred that the particle size (D50%) of either one be smaller than that of the other and it is more preferred that the ratio of the particle size of either one to that of the other be from 1 to 10. By this, the resistivity of the resulting electrode is reduced more effectively. This may be thought to be attributed to, for example, an increase in the contact area among the metal particles, such as the phosphorus-containing copper alloy particle and the silver particle, in the electrode.

From the viewpoint of the oxidation resistance and low resistivity of the electrode, the content of the silver particle in the electrode paste composition according to the present invention is preferably from 8.4% by mass to 85.5% by mass, and more preferably from 8.9% by mass to 80.1% by mass.

Further, in the present invention, from the viewpoint of the oxidation resistance and low resistivity of the electrode, taking the total amount of the above-described phosphorus-containing copper alloy particle and the silver particle as 100% by mass, the content of the phosphorus-containing copper alloy particle is preferably from 9% by mass to 88% by mass, and more preferably from 17% by mass to 77% by mass. By controlling the content of the phosphorus-containing copper alloy particle at 9% by mass or more with respect to the total amount of the phosphorus-containing copper alloy particle and the silver particle, for example, when the above-described glass particle contains divanadium pentoxide, the reaction between silver and vanadium is suppressed, so that the volume resistance of the resulting electrode is further reduced. In addition, in a treatment of a silicon substrate on which an electrode is formed with an aqueous hydrofluoric acid solution, which treatment is performed for the purpose of improving the energy conversion efficiency of a resulting photovoltaic cell, the resistance of the electrode material against the aqueous hydrofluoric acid solution (a property that the electrode material is not detached from the silicon substrate by the aqueous hydrofluoric acid solution) is improved. Moreover, by controlling the content of the above-described phosphorus-containing copper alloy particle at 88% by mass or less, the contact between copper contained therein and the silicon substrate is further inhibited, so that the contact resistance of the resulting electrode is further reduced.

Further, in the electrode paste composition according to the present invention, from the viewpoint of the oxidation resistance, low resistivity of the electrode and coating property on the silicon substrate, the total content of the above-described phosphorus-containing copper alloy particle and the silver particle is preferably from 70% by mass to 94% by mass, more preferably from 72% by mass to 92% by mass, still more preferably from 72% by mass to 90% by mass, and particularly preferably from 74% by mass to 88% by mass.

By controlling the total content of the above-described phosphorus-containing copper alloy particle and the silver particle at 70% by mass or more, a viscosity suitable for providing the electrode paste composition may be easily attained. Further, by controlling the total content of the above-described phosphorus-containing copper alloy particle and the silver particle at 94% by mass or less, the occurrence of abrasion when providing the electrode paste composition may be inhibited more effectively.

Further, in the electrode paste composition according to the present invention, from the viewpoint of the oxidation and low resistivity of the electrode, it is preferred that the total content of the above-described phosphorus-containing copper alloy particle and the silver particle, the content of the above-described glass particle and the total content of the above-described solvent and the resin be from 70% by mass to 94% by mass, from 0.1% by mass to 10% by mass and from 3% by mass to 29.8% by mass, respectively, and it is more preferred that the total content of the above-described phosphorus-containing copper alloy particle and the silver particle, the content of the above-described glass particle and the total content of the above-described solvent and the resin be from 74% by mass to 88% by mass, from 1% by mass to 7% by mass and from 7% by mass to 20% by mass, respectively.

(Phosphorus-Containing Compound)

The above-described electrode paste composition may further contain at least one phosphorus-containing compound. By this, the oxidation resistance is improved more effectively and the resistivity of the resulting electrode is further reduced. In addition, the phosphorus elements in the phosphorus-containing compound are diffused as n-type dopant in the silicon substrate, so that there may be obtained an effect that the power generation efficiency is improved when the electrode paste composition is used to prepare a photovoltaic cell may also be attained.

As the above-described phosphorus-containing compound, from the viewpoint of the oxidation resistance and low resistivity of the electrode, a compound having a high content of phosphorus atom in the molecule, which does not undergo evaporation or decomposition at a temperature condition of about 200° C.

Specific examples of the above-described phosphorus-containing compound include phosphorus-based inorganic acids such as phosphoric acid; phosphates such as ammonium phosphate; phosphoric acid esters such as phosphoric acid alkyl esters and phosphoric acid aryl esters; cyclic phosphazenes such as hexaphenoxyphosphazene; and derivatives thereof.

The phosphorus-containing compound in the present invention is, from the viewpoint of the oxidation resistance and low resistivity of the electrode, preferably at least one selected from the group consisting of phosphoric acid, ammonium phosphate, phosphoric acid esters and cyclic phosphazenes, and more preferably at least one selected from the group consisting of phosphoric acid esters and cyclic phosphazenes.

From the viewpoint of the oxidation resistance and low resistivity of the electrode, the content of the above-described phosphorus-containing compound in the present invention is preferably from 0.5% by mass to 10% by mass, and more preferably from 1% by mass to 7% by mass, with respect to the total mass of the electrode paste composition.

Further, in the present invention, the electrode paste composition contains, as the phosphorus-containing compound, preferably at least one selected from the group consisting of phosphoric acid, ammonium phosphate, phosphoric acid esters and cyclic phosphazenes in an amount of from 0.5% by mass to 10% by mass with respect to the total mass of the electrode paste composition, and more preferably at least one selected from the group consisting of phosphoric acid esters and cyclic phosphazenes in an amount of from 1% by mass to 7% by mass with respect to the total mass of the electrode paste composition.

(Other Components)

Further, in addition to those components described in the above, the above-described electrode paste composition may further contain, as required, other component(s) normally used in the art. Examples thereof include plasticizers, dispersing agents, surfactants, inorganic binders, metal oxides, ceramics and organic metal compounds.

The method of producing the above-described electrode paste composition is not particularly restricted. The electrode paste composition may be produced by dispersing and mixing, for example, the above-described phosphorus-containing copper alloy particle, glass particle, solvent, resin and silver particle which is included as required by a dispersing and mixing method which is normally employed.

Further, although it is preferred that a flux not be applied in the present invention, if a flux is applied, it is preferred that a flux be coated on the electrode surface. The flux when used for the electrode is the same as the one used in the later-described solder layer and their preferred ranges are also the same. In addition, the method of applying the flux on the electrode is also the same as the case where the flux is applied on the solder layer.

(Method of Producing Electrode)

As for the method of producing an electrode using the above-described electrode paste composition, an electrode may be formed in a desired region by providing the electrode paste composition on a region where an electrode is to be formed and then drying and sintering the resultant. By using the above-described electrode paste composition, an electrode having a low resistivity may be formed even when the sinter treatment is performed in the presence of oxygen (for example, in the air).

Specifically, for example, in cases where a photovoltaic cell electrode is formed using the above-described electrode paste composition, a photovoltaic cell electrode having a low resistivity may be formed in a desired shape by providing the electrode paste composition on a silicon substrate in a desired shape and then drying and sintering the resultant.

Examples of the method of providing the electrode paste composition on a silicon substrate include screen printing, ink-jet methods and dispenser methods; from the viewpoint of the productivity, it is preferred that the electrode paste composition be applied by screen printing.

In cases where the above-described electrode paste composition is applied by screen printing, it is preferred that the electrode paste composition have a viscosity in the range of from 80 Pa·s to 1,000 Pa·s. Here, the viscosity of the electrode paste composition is measured at 25° C. using a Brookfield HBT viscometer.

The amount of the above-described electrode paste composition to be applied may be selected as appropriate in accordance with the size of the electrode to be formed. For example, the electrode paste composition may be applied in an amount of from 2 g/m² to 10 g/m², and preferably from 4 g/m² to 8 g/m².

Further, as the heat treatment conditions (sinter conditions) for forming an electrode using the above-described electrode paste composition, those that are normally employed in the art may be adopted.

In general, the heat treatment temperature (sinter temperature) is from 800° C. to 900° C.; however, in cases where the above-described electrode paste composition is used, a lower temperature may be adopted as a heat treatment condition and, for example, an electrode having excellent characteristics may be formed at a heat treatment temperature of from 600° C. to 850° C.

Further, the heat treatment time may be selected as appropriate in accordance with the heat treatment temperature and the like and it may be, for example, from 1 second to 20 seconds.

(Oxide Layer)

The electrode according to the present invention has an oxide layer on the surface thereof. Whether or not the electrode has an oxide layer on the surface thereof may be verified by energy dispersive X-ray analysis (EDX).

[Solder Layer]

The solder layer according to the present invention is provided on top of the above-described oxide layer of the electrode surface and connects the above-described electrode with a wiring member and the like. It is desired that the solder layer according to the present invention contain no flux. By allowing the above-described solder layer to contain no flux, when bonding the solder layer onto the above-described electrode, the process of drying the solvent component contained in the above-described flux may be omitted. In addition, the flux washing process after bonding the solder layer onto the electrode may also be omitted and the corrosive reaction of the above-described flux against the electrode may also be inhibited. It is possible to use a flux; however, when a flux is used, it is preferred to employ a flux having relatively weak activity from the reasons described in the above, that is, a rosin-based flux, a RMA-based flux or an R-type flux.

The type of the solder material constituting the above-described solder layer is the same as described in the above, and the preferred range thereof is also the same as described in the above.

[Wiring Member]

The wiring member according to the present invention is provided on the above-described solder layer and connected by the solder layer onto the above-described oxide layer of the electrode surface. Examples of the wiring member according to the present invention include solder-coated copper wires (generally called “tab wire”), silver-coated copper wires, bare copper wires and bare silver wires. It is noted that the wiring member is not restricted to these as long as it is electrically conductive. Further, the cross-sectional shape thereof is not restricted and may be, for example, rectangular, elliptical or circular.

[Use of Element]

The use of the element according to the present invention is not particularly restricted and it may be used as a photovoltaic cell element, electroluminescence element and the like.

<Method of Producing Element>

The method of producing an element according to the present invention includes the processes of: (1) preparing a substrate which has a semiconductor substrate and an electrode in which the electrode is provided on the above-described semiconductor substrate, contains phosphorus and copper and has an oxide layer on the surface; and (2) bonding a solder layer on the above-described oxide layer by performing a heat treatment at a temperature of from the solidus temperature to the liquidus temperature of the solder layer.

In the above-described process of preparing a substrate, the above-described substrate may be a commercially available product or one which is prepared by using the electrode paste composition as described in the above, as long as the substrate has a semiconductor substrate and an electrode which contains phosphorus and copper has an oxide layer on the surface thereof.

In the above-described process of bonding a solder layer, a solder layer is bonded onto the oxide layer on the surface of the above-described electrode. In this case, the bonding is attained by performing a heat treatment at a temperature of from the solidus temperature to the liquidus temperature of the solder layer. This bonding method is the same as that of the solder bonded body.

<Photovoltaic Cell Element>

The photovoltaic cell element according to the present invention is one which the above-described substrate in the above-described element has an impurity diffusion layer on which the above-described electrode having an oxide layer on the surface thereof is formed and on this oxide layer, a solder layer is formed. By this, a photovoltaic cell element having excellent characteristics may be obtained and excellent productivity of the photovoltaic cell may be attained. It is noted here that the electrode having an oxide layer on the surface thereof may be a surface electrode arranged on the light-receiving surface side of the photovoltaic cell element or an output extraction electrode arranged on the back surface side of the photovoltaic cell element.

Here, the term “photovoltaic cell element” used herein refers to one which has a silicon substrate on which a pn junction is formed and an electrode formed on the silicon substrate. Further, the term “photovoltaic cell” used herein refers to one which is constituted by providing a wiring member on the electrode of the photovoltaic cell element and connecting, as required, plural photovoltaic cell elements via the wiring member.

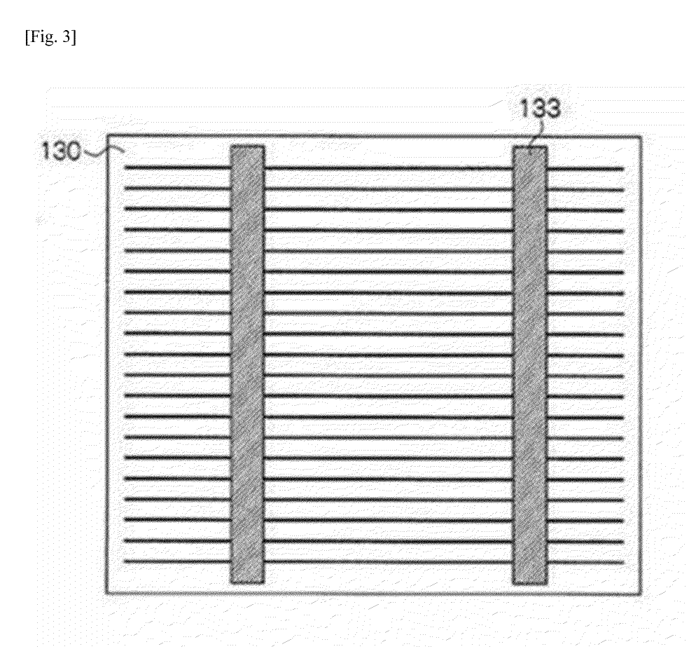

A specific example of the photovoltaic cell according to the present invention will now be described with reference to the drawings; however, the present invention is not restricted thereto. FIGS. 2, 3 and 4 show a cross-sectional view, a schematic diagram of the light-receiving surface and a schematic diagram of the back surface of one example of representative photovoltaic cell element, respectively.

Normally, monocrystalline or polycrystalline Si or the like is employed as a semiconductor substrate 130 of photovoltaic cell element. This semiconductor substrate 130 contains boron and the like, constituting a p-type semiconductor. On the light-receiving surface side thereof, in order to inhibit reflection of sunlight, irregularities (texture, not shown in figures) are formed by etching. As shown in FIG. 2, on the light-receiving surface side, phosphorus and the like are doped, a diffusion layer 131 of n-type semiconductor is provided in a thickness in the order of sub-microns and a pn junction portion is formed at the boundary with the p-type bulk portion. In addition, on the light-receiving surface side, an anti-reflection layer 132 of silicon nitride or the like having a film thickness of about 100 nm is provided on the diffusion layer 131 by a vapor deposition method or the like.

Next, a light-receiving surface electrode 133 provided on the light-receiving surface side, a current collecting electrode 134 formed on the back surface and an output extraction electrode 135 will be described. The light-receiving surface electrode 133 and the output extraction electrode 135 are formed from the above-described electrode paste composition. Further, the current collecting electrode 134 is formed from an aluminum electrode paste composition containing glass powder. These electrodes may be formed by applying the above-described paste composition in a desired pattern by screen printing or the like and drying the resultant, followed by sinter thereof in the air at a temperature of about from 600° C. to 850° C.

Here, on the light-receiving surface side, the glass particles contained in the above-described electrode paste composition forming the light-receiving surface electrode 133 undergo a reaction with the anti-reflection layer 132 (fire-through) to form an electrical connection (ohmic contact) between the light-receiving surface electrode 133 and the diffusion layer 131.

In the present invention, by using the above-described electrode paste composition to form the light-receiving surface electrode 133, even though copper is used as a conductive metal, the oxidation may be inhibited, whereby the resulting light-receiving surface electrode 133 having a low resistivity is formed with excellent productivity. Further, the outer surface of the light-receiving surface electrode 133 has an oxide layer (not shown in figures) and by bonding a solder layer on this oxide layer, the light-receiving surface electrode 133 and the solder layer may be electrically connected.

Further, on the back surface side, during sinter, the aluminum contained in the aluminum electrode paste composition forming the current collecting electrode 134 is dispersed on the back surface of the semiconductor substrate 130 to form an electrode component diffusion layer 136, thereby ohmic contact may be attained between the semiconductor substrate 130 and the current collecting electrode 134/the output extraction electrode 135.

In the present invention, by using the above-described electrode paste composition to form the output extraction electrode 135, even though copper is used as a conductive metal, the oxidation may be inhibited, whereby the resulting output extraction electrode 135 having a low resistivity is formed with excellent productivity. Further, the outer surface of the output extraction electrode 135 has an oxide layer (not shown in figures) and by bonding a solder layer on this oxide layer, the output extraction electrode 135 and the solder layer may be electrically connected.

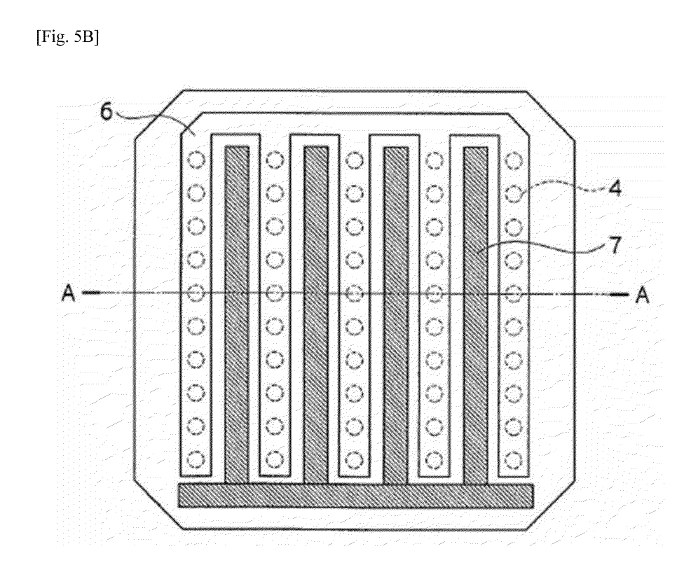

Further, FIG. 5 shows one example of a back contact-type photovoltaic cell element, which is another embodiment of the photovoltaic cell element according to the present invention. FIG. 5A is a perspective view showing the light-receiving surface and the structure of the A-A cross-section and FIG. 5B is a plan view showing the structure of the back surface electrode.

As shown in FIG. 5A, on a cell wafer 1, which is composed of a silicon substrate of a p-type semiconductor, through-holes penetrating both the light-receiving surface and the back surface are formed by laser drilling, etching or the like. Further, on the light-receiving surface side, a light incidence efficiency-improving texture (not shown in figures) is formed. Also, on the light-receiving surface side, an n-type semiconductor layer 3 is formed by an n-type diffusion treatment and an anti-reflection film (not shown in figures) is formed on the n-type semiconductor layer 3. These are produced by the same process as in the case of a conventional crystalline Si-type photovoltaic cell element.

Next, by a printing method or an ink-jet method, the electrode paste composition according to the present invention is filled into the through-holes that are previously formed and on the light-receiving surface side, the electrode paste composition according to the present invention is printed in a grid shape, so that a composition layer constituting through-hole electrodes 4 and current collecting grid electrodes 2 is formed.

Here, as for the paste used for the filling and printing, it is preferable that pastes having an optimum composition, such as viscosity, be used in the respective processes; however, a paste of the same composition may be used to perform the filling and printing altogether.

Meanwhile, on the opposite side of the light-receiving surface (back surface side), a high-concentration doped layer 5 is formed in order to prevent carrier recombination. Here, as the impurity element forming the high-concentration doped layer 5, boron (B) or aluminum (Al) is used, and a p⁺ layer is formed. This high-concentration doped layer 5 may be formed by carrying out a thermal diffusion treatment using, for example, B as a diffusion source in the element production process before forming the above-described anti-reflection film. Alternatively, in cases where Al is used, the high-concentration doped layer 5 may be formed by printing an Al paste on the opposite surface side in the above-described printing process.

Thereafter, by performing sinter at from 650° C. to 850° C., the above-described electrode paste composition, which has been filled into the above-described through-holes and printed on the anti-reflection film formed on the light-receiving surface side, attains ohmic contact with the underlying n-type layer by fire-through effect.

Further, on the opposite surface side, as shown in the plan view of FIG. 5B, the electrode paste composition according to the present invention is printed and sintered in the stripe shape on both the n-side and the p-side to form back surface electrodes 6 and 7.

In the present invention, by using the above-described electrode paste composition to form the back surface electrodes 6 and 7, even though copper is used as a conductive metal, the oxidation may be inhibited, whereby the back surface electrodes 6 and 7 having a low resistivity are formed with excellent productivity. Further, the outer surfaces of the back surface electrodes 6 and 7 have an oxide layer (not shown in figures) and by bonding a solder layer (not shown in figures) on this oxide layer, the back surface electrodes 6 and 7 and the solder layer may be electrically connected.

It is noted here that the electrode having an oxide layer on the surface thereof, which is formed by using the photovoltaic cell electrode paste composition according to the present invention and the above-described composition, and the solder layer bonded on the oxide layer are not restricted to such application of photovoltaic cell electrodes described in the above and may also be suitably used in applications such as electrode wirings and shield wirings of plasma displays, ceramic condensers, antenna circuits, various sensor circuits and heat dissipation materials of semiconductor devices.

<Method of Producing Photovoltaic Cell Element>

The photovoltaic cell element according to the present invention is produced in the same manner as the above-described element. In the production of the photovoltaic cell element, as the above-described semiconductor substrate, one which has an impurity diffusion layer to be pn-joined is employed, and on this impurity diffusion layer, the above-described electrodes are provided.

A photovoltaic substrate containing such semiconductor substrate, which has an impurity diffusion layer and is pn-joined, and the electrodes provided on the impurity diffusion layer may be a commercially available product, or it may also be prepared using the electrode paste composition as described in the above.

<Photovoltaic Cell>

The photovoltaic cell according to the present invention contains at least one photovoltaic cell element described in the above and is constituted in such a manner that a wiring member is arranged on the electrode of the photovoltaic cell element. The electrode has an oxide layer on the surface thereof and on this oxide layer, the wiring member is bonded with a solder layer. Since the above-described oxide layer is not removed by a flux or the like, the corrosive reaction of the above-described flux against the electrode may be inhibited. Further, by using no flux, when bonding the above-described solder layer onto the above-described electrode, the process of drying the solvent component contained in the above-described flux may be omitted. In addition, the flux washing process after bonding the above-described solder layer onto the above-described electrode may also be omitted. As a result, a photovoltaic cell having excellent power generation performance, in which the above-described electrode having an oxide layer on the surface thereof, the solder layer and the wiring member are electrically connected, may be obtained.

The photovoltaic cell may also be connected, as required, with plural photovoltaic cell elements via the wiring member and may be constituted to be sealed with a sealing material as well. The above-described wiring member and sealing material are not particularly restricted and they may be selected as appropriate from those which are normally employed in the art.

### EXAMPLES

The present invention will now be described more concretely by way of examples thereof; however, the present invention is not restricted to the following examples. It is noted here that, unless otherwise specified, “part(s)” and “%” are by mass.

### Example 1

### (a) Preparation of Solder

A bar solder (Sn 50% by mass-Pb 50% by mass; manufactured by Shinfuji Burner Co., Ltd.) and a plate lead (Pb; manufactured by Kiyo Sangyo) were weighed to obtain 10 parts of tin and 90 parts of lead, which were then melted at 440° C. in a graphite crucible. The resultant was then poured into a mold and rapidly cooled to obtain a solid solder 1.

As a result of examining the cooling curve of the thus obtained solder 1 using a thermocouple and a pen recorder, the liquidus temperature and the solidus temperature were found to be 302° C. and 275° C., respectively.

### (b) Preparation of Solder Bonded Body

A glass (alkali-free glass #1737 manufactured by Corning Inc.) was employed as an oxide body to be bonded. The surface thereof was normal glass surface. The body to be bonded was heated on a hot plate (HP-1SA; manufactured by AS ONE Corporation) for a sufficient time period until the temperature became constant. As for the temperature, that of the glass surface was measured using a surface thermometer. The solder 1 prepared in the above was placed on the glass and pressed against an electrode using a soldering iron (RV-802AS manufactured by Taiyo Electric Ind. Co., Ltd.) whose temperature was set to be the same as that of the hot plate. Here, the temperatures of the hot plate and the soldering iron were each adjusted as shown in Table 1.

### (c) Evaluation of Bonding Property

As for the bonding property, the tensile bond strength was measured in accordance with JIS H8504 (Methods of Adhesion Test for Metallic Coatings) using a tensile tester (manufactured by Quad Group Inc.: thin-film adhesion strength measuring apparatus ROMULUS) and a stud-pin having a φ1.8-mm bonding surface (manufactured by Quad Group Inc.: φ1.8-mm copper stud-pin) and evaluated based on the following criteria. Evaluations of A, B and C were defined as satisfactory and an evaluation of D was defined as not-satisfactory.

A: The tensile bond strength was 3 N/φ1.8 mm or more with excellent adhesion.

B: Bonding was attained at a tensile bond strength in the range of from 1.5 N/φ1.8 mm to less than 3 N/φ1.8 mm.

C: Bonding was attained at a tensile bond strength of less than 1.5 N/φ1.8 mm, but the solder was somewhat repelled, or there was a problem in the bonding workability because of a large amount of solid content or the like even though bonding was attained.

D: Bonding was not attained (including those conditions where bonding was not attained due to repelling of the solder, a large amount of solid content or solidification of the solder).

The results of evaluating the bonding property at respective bonding temperatures are shown in Table 1. It is noted here that, in the following tables, “-” denotes that the solder bonded body was not evaluated.

### Example 2

A solder 2 was prepared in the same manner as in Example 1 except that the solder composition was changed from 10 parts of tin and 90 parts of lead to 20 parts of tin and 80 parts of lead. Then, the bonding temperature and the bonding property were evaluated in the same manner as in Example 1 except that the thus obtained solder 2 was used. Further, as a result of examining the cooling curve of the solder 2, the liquidus temperature and the solidus temperature were found to be 280° C. and 183° C., respectively. The results are shown in Table 1.

### Example 3

A solder 3 was prepared in the same manner as in Example 1 except that the solder composition was changed from 10 parts of tin and 90 parts of lead to 30 parts of tin and 70 parts of lead. Then, the bonding temperature and the bonding property were evaluated in the same manner as in Example 1 except that the thus obtained solder 3 was used. Further, as a result of examining the cooling curve of the solder 3, the liquidus temperature and the solidus temperature were found to be 255° C. and 183° C., respectively. The results are shown in Table 1.

### Example 4

A solder 4 was prepared in the same manner as in Example 1 except that the solder composition was changed from 10 parts of tin and 90 parts of lead to 45 parts of tin and 55 parts of lead. Then, the bonding temperature and the bonding property were evaluated in the same manner as in Example 1 except that the thus obtained solder 4 was used. Further, as a result of examining the cooling curve of the solder 4, the liquidus temperature and the solidus temperature were found to be 227° C. and 183° C., respectively. The results are shown in Table 2.

### Example 5

A solder 5 was prepared in the same manner as in Example 1 except that the bar solder (Sn 50% by mass-Pb 50% by mass) was used as-is as a solder. Then, the bonding temperature and the bonding property were evaluated in the same manner as in Example 1 except that the thus obtained solder 5 was used. Further, as a result of examining the cooling curve of the solder 5, the liquidus temperature and the solidus temperature were found to be 214° C. and 183° C., respectively. The results are shown in Table 2.

### Example 6

A solder 6 was prepared in the same manner as in Example 1 except that the bar solder (Sn 50% by mass-Pb 50% by mass) was changed to a bar solder (Sn 95% by mass-Pb 5% by mass; manufactured by E-Material Inc.) and that the solder composition was changed from 10 parts of tin and 90 parts of lead to 60 parts of tin and 40 parts of lead. Then, the bonding temperature and the bonding property were evaluated in the same manner as in Example 1 except that the thus obtained solder 6 was used. Further, as a result of examining the cooling curve of the solder 6, the liquidus temperature and the solidus temperature were found to be 188° C. and 183° C., respectively. The results are shown in Table 3.

### Example 7

A solder 7 was prepared in the same manner as in Example 6 except that the solder composition was changed from 60 parts of tin and 40 parts of lead to 62 parts of tin and 38 parts of lead. Then, the bonding temperature and the bonding property were evaluated in the same manner as in Example 6 except that the thus obtained solder 7 was used. Further, as a result of examining the cooling curve of the solder 7, the liquidus temperature and the solidus temperature could not be separated at 183° C. The results are shown in Table 3.

### Example 8

A solder 8 was prepared in the same manner as in Example 6 except that the solder composition was changed from 60 parts of tin and 40 parts of lead to 63 parts of tin and 37 parts of lead. Then, the bonding temperature and the bonding property were evaluated in the same manner as in Example 6 except that the thus obtained solder 8 was used. Further, as a result of examining the cooling curve of the solder 8, the liquidus temperature and the solidus temperature were found to be 185° C. and 183° C., respectively. The results are shown in Table 3.

### Example 9

A solder 9 was prepared in the same manner as in Example 6 except that the solder composition was changed from 60 parts of tin and 40 parts of lead to 70 parts of tin and 30 parts of lead. Then, the bonding temperature and the bonding property were evaluated in the same manner as in Example 6 except that the thus obtained solder 9 was used. Further, as a result of examining the cooling curve of the solder 9, the liquidus temperature and the solidus temperature were found to be 192° C. and 183° C., respectively. The results are shown in Table 3.

### Example 10

A solder 10 was prepared in the same manner as in Example 6 except that the solder composition was changed from 60 parts of tin and 40 parts of lead to 80 parts of tin and 20 parts of lead. Then, the bonding temperature and the bonding property were evaluated in the same manner as in Example 6 except that the thus obtained solder 10 was used. Further, as a result of examining the cooling curve of the solder 10, the liquidus temperature and the solidus temperature were found to be 205° C. and 183° C., respectively. The results are shown in Table 4.

### Example 11

A solder 11 was prepared in the same manner as in Example 6 except that the solder composition was changed from 60 parts of tin and 40 parts of lead to 90 parts of tin and 10 parts of lead. Then, the bonding temperature and the bonding property were evaluated in the same manner as in Example 6 except that the thus obtained solder 11 was used. Further, as a result of examining the cooling curve of the solder 11, the liquidus temperature and the solidus temperature were found to be 218° C. and 183° C., respectively. The results are shown in Table 4.

### Example 12

A solder 12 was prepared in the same manner as in Example 1 except that the bar solder and the plate lead were changed to a tin flat bar (manufactured by E-Material Inc.) and chipped bismuth (manufactured by E-Material Inc.) and that the solder composition was changed from 10 parts of tin and 90 parts of lead to 42 parts of tin and 58 parts of bismuth. Then, the bonding temperature and the bonding property were evaluated in the same manner as described in the above except that the thus obtained solder 12 was used. Further, as a result of examining the cooling curve of the solder 12, the liquidus temperature and the solidus temperature were found to be 141° C. and 139° C., respectively. The results are shown in Table 5.

### Example 13

A solder 13 was prepared in the same manner as in Example 12 except that a pure silver round wire (manufactured by Nitto Kagaku Co., Ltd.) was further used to change the solder composition from 42 parts of tin and 58 parts of bismuth to 42 parts of tin, 57 parts of bismuth and 1 part of silver. Then, the bonding temperature and the bonding property were evaluated in the same manner as described in the above except that the thus obtained solder 13 was used. Further, as a result of examining the cooling curve of the solder 13, the liquidus temperature and the solidus temperature were found to be 140° C. and 138° C., respectively. The results are shown in Table 5.

### Example 14

A solder 14 was prepared in the same manner as in Example 12 except that the solder composition was changed from 42 parts of tin and 58 parts of bismuth to 61 parts of tin and 39 parts of bismuth. Then, the bonding temperature and the bonding property were evaluated in the same manner as described in the above except that the thus obtained solder 14 was used. Further, as a result of examining the cooling curve of the solder 14, the liquidus temperature and the solidus temperature were found to be 177° C. and 138° C., respectively. The results are shown in Table 6.

### Example 15

A solder 15 was prepared in the same manner as in Example 12 except that the solder composition was changed from 42 parts of tin and 58 parts of bismuth to 56 parts of tin and 44 parts of bismuth. Then, the bonding temperature and the bonding property were evaluated in the same manner as described in the above except that the thus obtained solder 15 was used. Further, as a result of examining the cooling curve of the solder 15, the liquidus temperature and the solidus temperature were found to be 167° C. and 138° C., respectively. The results are shown in Table 6.

### Example 16

A solder 16 was prepared in the same manner as in Example 12 except that the solder composition was changed from 42 parts of tin and 58 parts of bismuth to 52 parts of tin and 48 parts of bismuth. Then, the bonding temperature and the bonding property were evaluated in the same manner as described in the above except that the thus obtained solder 16 was used. Further, as a result of examining the cooling curve of the solder 16, the liquidus temperature and the solidus temperature were found to be 158° C. and 138° C., respectively. The results are shown in Table 6.

### Comparative Example 1

The bonding temperature and the bonding property were evaluated in the same manner as in Example 1, except that a plate lead (Pb) was used as-is as the solder (solder Si). As a result of examining the cooling curve of the solder S1, the melting point (=liquidus temperature=solidus temperature) was found to be 327° C. The results are shown in Table 1.

Further, in each bonding temperature of Examples 1 to 16 and Comparative Example 1, each ratio of liquid phase in the solder layer as a whole was determined from an equilibrium diagram of the solder composition used, and was shown in Tables 7 to 12.

TABLE 1

| | Comparative | Exam- | Exam- | Exam- |
|---|---|---|---|---|
| | Example 1 | ple 1 | ple 2 | ple 3 |
| | Solder Composition | | | |
| | Sn—Pb (% by mass) | | | |
| Temperature (° C.) | 0-100 | 10-90 | 20-80 | 30-70 |
| 330 | D | D | D | D |
| 320 | D | D | D | D |
| 300 | D | A | D | D |
| 290 | D | A | D | D |
| 280 | D | C | B | D |
| 270 | D | D | A | D |
| 260 | D | D | A | D |
| 250 | D | D | B | A |
| 230 | D | D | C | A |
| 220 | D | D | C | B |
| 200 | D | D | C | C |
| Liquidus temperature (° C.) | 327 | 302 | 280 | 255 |
| Solidus temperature (° C.) | 327 | 275 | 183 | 183 |

TABLE 2

| | |
|---|---|
| Example 4 | Example 5 |

Solder Composition
Sn—Pb (% by mass)

| Temperature (° C.) | 45-55 | 50-50 |
|---|---|---|
| 260 | D | D |
| 250 | D | D |
| 230 | D | D |
| 220 | A | D |
| 210 | A | B |
| 200 | A | A |
| 190 | A | A |
| 185 | A | A |
| 180 | D | D |
| Liquidus temperature (° C.) | 227 | 214 |
| Solidus temperature (° C.) | 183 | 183 |

TABLE 3

| | Exam- | Exam- | Exam- | Exam- |
|---|---|---|---|---|
| | ple 6 | ple 7 | ple 8 | ple 9 |
| | Solder Composition | | | |
| | Sn—Pb (% by mass) | | | |
| Temperature (° C.) | 60-40 | 62-38 | 63-37 | 70-30 |
| 200 | D | D | D | D |
| 195 | D | D | D | D |
| 190 | D | D | D | B |
| 187 | B | D | D | A |
| 185 | A | D | B | A |
| 183 | A | C | A | A |
| 180 | D | D | D | D |
| Liquidus temperature (° C.) | 188 | 183 | 185 | 192 |
| Solidus temperature (° C.) | 183 | 183 | 183 | 183 |

TABLE 4

| | |
|---|---|
| Example 10 | Example 11 |

Solder Composition
Sn—Pb (% by mass)

| Temperature (° C.) | 80-20 | 90-10 |
|---|---|---|
| 260 | D | D |
| 250 | D | D |
| 230 | D | D |
| 220 | D | D |
| 210 | D | A |
| 200 | A | B |
| 190 | A | C |
| 185 | A | C |
| 180 | D | D |
| Liquidus temperature (° C.) | 205 | 218 |
| Solidus temperature (° C.) | 183 | 183 |

TABLE 5

| | |
|---|---|
| Example 12 | Example 13 |

Solder Composition
Sn—Bi—Ag (% by mass)

| Temperature (° C.) | 42-58-0 | 42-57-1 |
|---|---|---|
| 190 | D | — |
| 170 | D | — |
| 145 | D | — |
| 142 | C | D |
| 141 | B | C |
| 140 | A | B |
| 139 | A | A |
| 138 | C | A |
| 137 | D | C |
| 136 | D | D |
| 135 | D | — |
| Liquidus temperature (° C.) | 141 | 140 |
| Solidus temperature (° C.) | 139 | 138 |

TABLE 6

| | Example 14 | Example 15 | Example 16 |
|---|---|---|---|
| | Solder Composition | | |
| | Sn—Bi (% by mass) | | |
| Temperature (° C.) | 61-39 | 56-44 | 52-48 |
| 180 | D | D | D |
| 171 | C | — | — |
| 165 | A | C | — |
| 161 | — | B | — |
| 158 | B | — | C |
| 154 | — | A | — |
| 150 | — | — | B |
| 147 | — | A | — |
| 145 | — | — | A |
| 140 | — | — | A |
| 138 | C | C | C |
| 135 | D | D | D |
| Liquidus temperature (° C.) | 177 | 167 | 158 |
| Solidus temperature (° C.) | 138 | 138 | 138 |

TABLE 7

| | Comparative | Exam- | Exam- | Exam- |
|---|---|---|---|---|
| | Example 1 | ple 1 | ple 2 | ple 3 |
| | Solder Composition | | | |
| | Sn—Pb (% by mass) | | | |
| Temperature (° C.) | 0-100 | 10-90 | 20-80 | 30-70 |
| 330 | 100% | 100% | 100% | 100% |
| 320 | 0% | 100% | 100% | 100% |
| 300 | 0% | 70% | 100% | 100% |
| 290 | 0% | 27% | 100% | 100% |
| 280 | 0% | 6% | 99% | 100% |
| 270 | 0% | 0% | 66% | 100% |
| 260 | 0% | 0% | 47% | 100% |
| 250 | 0% | 0% | 34% | 84% |
| 230 | 0% | 0% | 18% | 55% |
| 220 | 0% | 0% | 13% | 46% |
| 200 | 0% | 0% | 5% | 32% |
| Liquidus temperature (° C.) | 327 | 302 | 280 | 255 |
| Solidus temperature (° C.) | 327 | 275 | 183 | 183 |

TABLE 8

| | |
|---|---|
| Example 4 | Example 5 |

Solder Composition
Sn—Pb (% by mass)

| Temperature (° C.) | 45-55 | 50-50 |
|---|---|---|
| 260 | 100% | 100% |
| 250 | 100% | 100% |
| 230 | 100% | 100% |
| 220 | 95% | 100% |
| 210 | 83% | 97% |
| 200 | 72% | 86% |
| 190 | 64% | 76% |
| 185 | 61% | 72% |
| 180 | 0% | 0% |
| Liquidus temperature (° C.) | 227 | 214 |
| Solidus temperature (° C.) | 183 | 183 |

TABLE 9

| | Exam- | Exam- | Exam- | Exam- |
|---|---|---|---|---|
| | ple 6 | ple 7 | ple 8 | ple 9 |
| | Solder Composition | | | |
| | Sn—Pb (% by mass) | | | |
| Temperature (° C.) | 60-40 | 62-38 | 63-37 | 70-30 |
| 200 | 100% | 100% | 100% | 100% |
| 195 | 100% | 100% | 100% | 100% |
| 190 | 100% | 100% | 100% | 93% |
| 187 | 97% | 100% | 100% | 85% |
| 185 | 96% | 100% | 99% | 81% |
| 183 | 95% | 99% | 97% | 77% |
| 180 | 0% | 0% | 0% | 0% |
| Liquidus temperature (° C.) | 188 | 183 | 185 | 192 |
| Solidus temperature (° C.) | 183 | 183 | 183 | 183 |

TABLE 10

| | |
|---|---|
| Example 10 | Example 11 |

Solder Composition
Sn—Pb (% by mass)

| Temperature (° C.) | 80-20 | 90-10 |
|---|---|---|
| 260 | 100% | 100% |
| 250 | 100% | 100% |
| 230 | 100% | 100% |
| 220 | 100% | 100% |
| 210 | 100% | 60% |
| 200 | 83% | 38% |
| 190 | 59% | 26% |
| 185 | 52% | 23% |
| 180 | 0% | 0% |
| Liquidus temperature (° C.) | 205 | 218 |
| Solidus temperature (° C.) | 183 | 183 |

TABLE 11

| | |
|---|---|
| Example 12 | Example 13 |

Solder Composition
Sn—Bi—Ag (% by mass)

| Temperature (° C.) | 42-58-0 | 42-57-1 |
|---|---|---|
| 190 | 100% | — |
| 170 | 100% | — |
| 145 | 100% | — |
| 142 | 100% | 100% |
| 141 | 99% | 100% |
| 140 | 98% | 99% |
| 139 | 97% | 98% |
| 138 | 0% | 97% |
| 137 | 0% | 0% |
| 136 | 0% | 0% |
| 135 | 0% | — |
| Liquidus temperature (° C.) | 141 | 140 |
| Solidus temperature (° C.) | 139 | 138 |

TABLE 12

| | Example 14 | Example 15 | Example 16 |
|---|---|---|---|
| | Solder Composition | | |
| | Sn—Bi (% by mass) | | |
| Temperature (° C.) | 61-39 | 56-44 | 52-48 |
| 180 | 100% | 100% | 100% |
| 171 | 90% | — | — |
| 165 | 80% | 99% | — |
| 161 | — | 90% | — |
| 158 | 70% | — | 99% |
| 154 | — | 80% | — |
| 150 | — | — | 90% |
| 147 | — | 70% | — |
| 145 | — | — | 80% |
| 140 | — | — | 75% |
| 138 | 50% | 62% | 70% |
| 135 | 0% | 0% | 0% |
| Liquidus temperature (° C.) | 177 | 167 | 158 |
| Solidus temperature (° C.) | 138 | 138 | 138 |

As shown in Tables 1 to 6, regardless of the composition of the solder material, by subjecting the solder material to a heat treatment at a temperature of from the solidus temperature to the liquidus temperature thereof, a solder layer was bonded to the oxide body to be bonded with excellent bonding property.

### Example 17

As a result of evaluating the bonding temperature and the bonding property in the same manner as in Example 5 except that the oxide body to be bonded was changed from the alkali-free glass to a quartz glass (manufactured by Shin-Etsu Chemical Co., Ltd.; synthetic quartz glass having a normal glass surface), the thus obtained solder bonded body was found to exhibit excellent bonding property in the same manner as the above-described Example 5.

### Example 18

As a result of evaluating the bonding temperature and the bonding property in the same manner as in Example 5 except that the oxide body to be bonded was changed from the alkali-free glass to an ITO (indium tin oxide) film formed on an alkali-free glass by vapor deposition, the thus obtained solder bonded body was found to exhibit excellent bonding property at a temperature of from its solidus temperature to liquidus temperature in the same manner as the above-described Example 5.

### Example 19

As a result of evaluating the bonding temperature and the bonding property in the same manner as in Example 5 except that the oxide body to be bonded was changed from the alkali-free glass to an alumina ceramic (oxide ceramic), the thus obtained solder bonded body was found to exhibit excellent bonding property at a temperature of from its solidus temperature to liquidus temperature in the same manner as the above-described Example 5.

### Example 20

As a result of evaluating the bonding temperature and the bonding property in the same manner as in Example 5 except that the oxide body to be bonded was changed from the alkali-free glass to copper, the thus obtained solder bonded body was found to exhibit excellent bonding property at a temperature of from its solidus temperature to liquidus temperature in the same manner as the above-described Example 5. The copper surface is covered with an oxide film composed of copper oxide; therefore, in ordinary soldering operation, it is required to apply an appropriate flux for the purpose of removing the above-described oxide film and wash-off this flux after completion of the soldering operation. In the solder bonded body according to the present invention, such an application of a flux may be eliminated, so that the flux-washing process may be omitted.

### Sample Example 1

### (a) Preparation of Electrode paste Composition

A phosphorus-containing copper alloy containing 7% by mass of phosphorus was prepared and this was dissolved and powderized by a water atomization method, followed by drying and classification. The thus classified powders were blended and subjected to deoxygenation and dehydration treatments to prepare a phosphorus-containing copper alloy particle containing 7% by mass of phosphorus (hereinafter, may be abbreviated as “Cu7P”). Here, the particle size (D50%) of the phosphorus-containing copper alloy particle was 5 μm.

A glass composed of 3 parts of silicon dioxide (SiO₂), 60 parts of lead oxide (PbO), 18 parts of boron oxide (B₂O₃), 5 parts of bismuth oxide (Bi₂O₃), 5 parts of aluminum oxide (Al₂O₃) and 9 parts of zinc oxide (ZnO) (hereinafter, may be abbreviated as “G1”) was prepared. The thus obtained glass G1 had a softening point of 420° C. and a crystallization temperature of higher than 600° C.

Using the thus obtained glass G1, a glass particle having a particle size (D50%) of 1.7 μm was obtained.

Then, 56.1 parts of the phosphorus-containing copper alloy particle Cu7P obtained in the above, 29.0 parts of tin particle (Sn; particle size (D50%) of 10.0 μm; purity of 99.9% or more), 1.7 parts of the glass G1 particle and 13.2 parts of terpineol (isomeric mixture) solution containing 3% by mass of ethyl cellulose (EC, weight average molecular weight: 190,000) were mixed and stirred in an agate mortar for 20 minutes to prepare an electrode paste composition Cu7PG1.

### (b) Preparation of an Electrode Having an Oxide Layer on the Surface Thereof

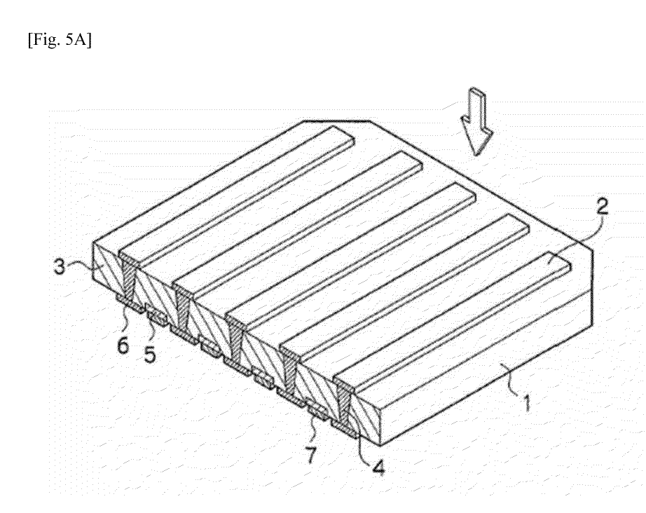

On a semiconductor silicon substrate, the thus obtained electrode paste composition Cu7PG1 was printed by a screen printing method to form an electrode pattern as shown in the output extraction electrode of FIG. 4. The printing conditions (mesh of the screen printing plate, printing speed and printing pressure) were adjusted as appropriate such that the electrode pattern had a width of 4 mm and a film thickness of 15 μm after sinter. The resultant was placed in an oven heated at 150° C. for 15 minutes to remove the solvent by evaporation.

Thereafter, in an infrared rapid heating furnace, the resultant was subjected to a heat treatment (sinter) in the air at 600° C. for 10 seconds to obtain an output extraction electrode. The surface of the thus obtained output extraction electrode had a Sn—P—O-based glass oxide layer and a copper-based oxide layer formed thereon. The Sn—P—O-based glass oxide layer and the copper-based oxide layer were verified using an energy dispersive X-ray analyzer (HITACHI scanning electron microscope SU1510).

### (c) Preparation of Solder

A bar solder (Sn 50% by mass-Pb 50% by mass; manufactured by Shinfuji Burner Co., Ltd.) and a plate lead (Pb; manufactured by Kiyo Sangyo) were weighed to obtain 10 parts of tin and 90 parts of lead, which were then melted at 450° C. in a graphite crucible. The resultant was then poured into a mold and rapidly cooled to obtain a solid solder 1. As a result of examining the cooling curve of the thus obtained solder 1, the liquidus temperature and the solidus temperature were found to be 302° C. and 275° C., respectively.

### (d) Evaluation of Bonding Property

The bonding property was evaluated in the same manner as in Example 1.

### Sample Example 2

The bonding temperature and the bonding property were evaluated in the same manner as in Sample Example 1 except that the solder composition was changed from 10 parts of tin and 90 parts of lead to 20 parts of tin and 80 parts of lead to prepare a solder 2. Further, as a result of examining the cooling curve of the thus obtained solder 2, the liquidus temperature and the solidus temperature were found to be 280° C. and 183° C., respectively. The results are shown in Table 13.

### Sample Example 3

The bonding temperature and the bonding property were evaluated in the same manner as in Sample Example 1 except that the solder composition was changed from 10 parts of tin and 90 parts of lead to 30 parts of tin and 70 parts of lead to prepare a solder 3. Further, as a result of examining the cooling curve of the thus obtained solder 3, the liquidus temperature and the solidus temperature were found to be 255° C. and 183° C., respectively. The results are shown in Table 13.

### Sample Example 4

The bonding temperature and the bonding property were evaluated in the same manner as in Sample Example 1 except that the solder composition was changed from 10 parts of tin and 90 parts of lead to 45 parts of tin and 55 parts of lead to prepare a solder 4. Further, as a result of examining the cooling curve of the thus obtained solder 4, the liquidus temperature and the solidus temperature were found to be 227° C. and 183° C., respectively. The results are shown in Table 14.

### Sample Example 5

The bonding temperature and the bonding property were evaluated in the same manner as in Sample Example 1 except that a solder 5 was prepared using, as a solder, the bar solder (Sn 50% by mass-Pb 50% by mass) as is. Further, as a result of examining the cooling curve of the thus obtained solder 5, the liquidus temperature and the solidus temperature were found to be 214° C. and 183° C., respectively. The results are shown in Table 14.

### Sample Example 6

The bonding temperature and the bonding property were evaluated in the same manner as in Sample Example 1 except that the bar solder (Sn 50% by mass-Pb 50% by mass) was changed to a bar solder (Sn 95% by mass-Pb 5% by mass; manufactured by E-Material Inc.) and the solder composition was changed from 10 parts of tin and 90 parts of lead to 60 parts of tin and 40 parts of lead to prepare a solder 6. Further, as a result of examining the cooling curve of the thus obtained solder 6, the liquidus temperature and the solidus temperature were found to be 188° C. and 183° C., respectively. The results are shown in Table 15.

### Sample Example 7

The bonding temperature and the bonding property were evaluated in the same manner as in Sample Example 6 except that the solder composition was changed from 60 parts of tin and 40 parts of lead to 62 parts of tin and 38 parts of lead to prepare a solder 7. Further, as a result of examining the cooling curve of the thus obtained solder 7, the liquidus temperature and the solidus temperature could not be separated at 183° C. The results are shown in Table 15.

### Sample Example 8

The bonding temperature and the bonding property were evaluated in the same manner as in Sample Example 6 except that the solder composition was changed from 60 parts of tin and 40 parts of lead to 63 parts of tin and 37 parts of lead to prepare a solder 8. Further, as a result of examining the cooling curve of the thus obtained solder 8, the liquidus temperature and the solidus temperature were found to be 185° C. and 183° C., respectively. The results are shown in Table 15.

### Sample Example 9

The bonding temperature and the bonding property were evaluated in the same manner as in Sample Example 6 except that the solder composition was changed from 60 parts of tin and 40 parts of lead to 70 parts of tin and 30 parts of lead to prepare a solder 9. Further, as a result of examining the cooling curve of the thus obtained solder 9, the liquidus temperature and the solidus temperature were found to be 192° C. and 183° C., respectively. The results are shown in Table 15.

### Sample Example 10

The bonding temperature and the bonding property were evaluated in the same manner as in Sample Example 6 except that the solder composition was changed from 60 parts of tin and 40 parts of lead to 80 parts of tin and 20 parts of lead to prepare a solder 10. Further, as a result of examining the cooling curve of the thus obtained solder 10, the liquidus temperature and the solidus temperature were found to be 205° C. and 183° C., respectively. The results are shown in Table 16.

### Sample Example 11

The bonding temperature and the bonding property were evaluated in the same manner as in Sample Example 6 except that the solder composition was changed from 60 parts of tin and 40 parts of lead to 90 parts of tin and 10 parts of lead to prepare a solder 11. Further, as a result of examining the cooling curve of the thus obtained solder 11, the liquidus temperature and the solidus temperature were found to be 218° C. and 183° C., respectively. The results are shown in Table 16.

### Sample Comparative Example 1

The bonding temperature and the bonding property were evaluated in the same manner as in Sample Example 1, except that a plate lead (Pb) was used as-is as the solder (solder S1). As a result of examining the cooling curve of the thus obtained solder S1, the melting point (=liquidus temperature=solidus temperature) was found to be 327° C. The results are shown in Table 13.

TABLE 13

| | Sample | Sample | Sample | Sample |
|---|---|---|---|---|
| | Comparative | Exam- | Exam- | Exam- |
| | Example 1 | ple 1 | ple 2 | ple 3 |
| | Solder Composition | | | |
| | Sn—Pb (% by mass) | | | |
| Temperature (° C.) | 0-100 | 10-90 | 20-80 | 30-70 |
| 330 | D | D | D | D |
| 320 | D | D | D | D |
| 300 | D | A | D | D |
| 290 | D | A | D | D |
| 280 | D | C | B | D |
| 270 | D | D | A | D |
| 260 | D | D | A | D |
| 250 | D | D | B | A |
| 230 | D | D | C | A |
| 220 | D | D | C | B |
| 200 | D | D | C | C |
| Liquidus temperature (° C.) | 327 | 302 | 280 | 255 |
| Solidus temperature (° C.) | 327 | 275 | 183 | 183 |

TABLE 14

| | Sample Example 4 | Sample Example 5 |
|---|---|---|
| | Solder Composition | |
| | Sn—Pb (% by mass) | |
| Temperature (° C.) | 45-55 | 50-50 |
| 260 | D | D |
| 250 | D | D |
| 230 | D | D |
| 220 | A | D |
| 210 | A | B |
| 200 | A | A |
| 190 | A | A |
| 185 | A | A |
| 180 | D | D |
| Liquidus temperature (° C.) | 227 | 214 |
| Solidus temperature (° C.) | 183 | 183 |

TABLE 15

| | Sample | Sample | Sample | Sample |
|---|---|---|---|---|
| | Exam- | Exam- | Exam- | Exam- |
| | ple 6 | ple 7 | ple 8 | ple 9 |
| | Solder Composition | | | |
| | Sn—Pb (% by mass) | | | |
| Temperature (° C.) | 60-40 | 62-38 | 63-37 | 70-30 |
| 200 | D | D | D | D |
| 195 | D | D | D | D |
| 190 | D | D | D | B |
| 187 | B | D | D | A |
| 185 | A | D | B | A |
| 183 | A | C | A | A |
| 180 | D | D | D | D |
| Liquidus temperature (° C.) | 188 | 183 | 185 | 192 |
| Solidus temperature (° C.) | 183 | 183 | 183 | 183 |

TABLE 16

| | Sample Example 10 | Sample Example 11 |
|---|---|---|
| | Solder Composition | |
| | Sn—Pb (% by mass) | |
| Temperature (° C.) | 80-20 | 90-10 |
| 260 | D | D |
| 250 | D | D |
| 230 | D | D |
| 220 | D | D |
| 210 | D | A |
| 200 | A | B |
| 190 | A | C |
| 185 | A | C |
| 180 | D | D |
| Liquidus temperature (° C.) | 205 | 218 |
| Solidus temperature (° C.) | 183 | 183 |

As shown in Tables 13 to 16, in cases where a solder was bonded at a temperature of from its solidus temperature to liquidus temperature, excellent bonding property was exhibited.

### Example 21

### Preparation of Photovoltaic Cell Element

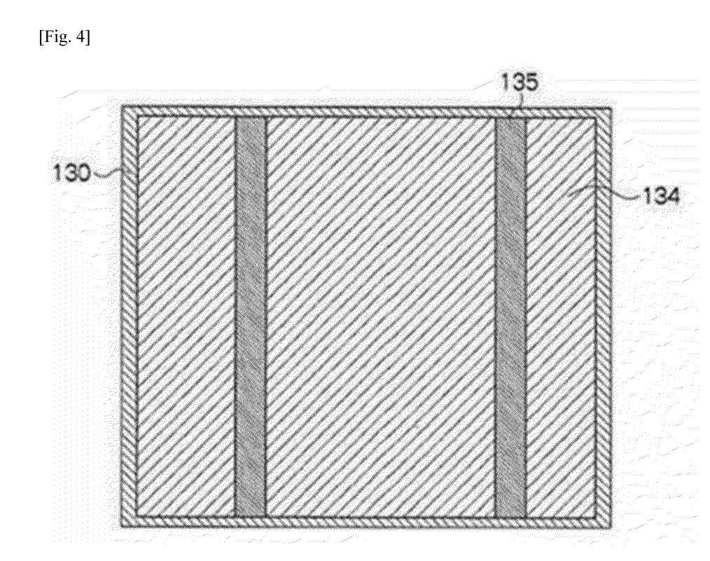

A p-type semiconductor substrate of 190 μm in film thickness, in which an n-type semiconductor layer, a texture and an anti-reflection film (silicon nitride film) are formed on the light-receiving surface, was prepared and cut out into a size of 125 mm×125 mm. On the light-receiving surface thereof, a silver electrode paste composition (conductor paste SOLAMET 159A manufactured by Du Pont) was printed by a screen printing method to form such an electrode pattern as shown in FIG. 3. The electrode pattern was constituted by finger lines of 150 μm in width and bus bars of 1.1 mm in width and the printing conditions (mesh of the screen printing plate, printing speed and printing pressure) were adjusted as appropriate such that the film thickness after sinter became about 5 μm. The resultant was placed in an oven heated at 150° C. for 15 minutes to remove the solvent by evaporation.

Thereafter, on the entire surface of the back side of the resulting semiconductor substrate except those portions where output extraction electrodes were going to be formed, an aluminum electrode paste (manufactured by PVG Solutions Inc., Solar Cell Paste (Al) Hyper BSF Al Paste) was printed in the same manner by screen printing as shown in FIG. 4. The printing conditions were adjusted as appropriate such that the film thickness after sinter became 40 μm. The resultant was placed in an oven heated at 150° C. for 15 minutes to remove the solvent by evaporation.

Further, in an infrared rapid heating furnace, the resultant was subjected to a heat treatment (sinter) in the air at 850° C. for 2 seconds to obtain a light-receiving surface electrode and a current collecting electrode.

Then, on the back side of the resultant, the electrode paste composition Cu7PG1 obtained in the above-described Sample Example 1 was printed by a screen printing method to form an electrode pattern as shown in the output extraction electrode of FIG. 4. The electrode pattern was constituted with bus bars of 4 mm in width and the printing conditions (mesh of the screen printing plate, printing speed and printing pressure) were adjusted as appropriate such that the film thickness after sinter became 15 μm. The resultant was placed in an oven heated at 150° C. for 15 minutes to remove the solvent by evaporation.

Thereafter, in an infrared rapid heating furnace, the resultant was subjected to a heat treatment (sinter) in the air at 600° C. for 10 seconds to obtain an output extraction electrode. The surface of the thus obtained output extraction electrode had a Sn—P—O-based glass oxide layer and a copper-based oxide layer formed thereon.

Next, on the thus obtained output extraction electrode, the solder shown in Table 17 was bonded at 300° C. in the same manner as in the above-described Sample Example 1. Further, on top thereof, a copper wire (tab wire) solder-coated with Su96.5Ag3Cu0.5 (code in accordance with JIS Z3282; liquidus temperature: 218° C., solidus temperature: 217° C.; nominal) was placed, and the resultant was placed on a 180° C. hot plate and bonded onto the output extraction electrode using a soldering iron whose temperature was set at 190° C.

Thereafter, by cooling the resultant, a desired photovoltaic cell element was prepared.

### Example 22

A photovoltaic cell element was prepared in the same manner as in Example 21 except that the solder was changed to that of Sample Example 5. The solder bonding temperature was 210° C.

### Example 23

A photovoltaic cell element was prepared in the same manner as in Example 22 except that the solder bonding temperature was changed to 190° C.

### Example 24

A photovoltaic cell element was prepared in the same manner as in Example 21 except that the solder was changed to that of Sample Example 6. The solder bonding temperature was 185° C.

### Example 25

A photovoltaic cell element was prepared in the same manner as in Example 21 except that the solder was changed to that of Sample Example 11. The solder bonding temperature was 210° C.

### Example 26

A photovoltaic cell element was prepared in the same manner as in Example 25 except that the solder bonding temperature was changed to 200° C.

### Comparative Example 21

A photovoltaic cell element was prepared in the same manner as in Example 21 except that the composition used for the formation of an output extraction electrode was changed from Cu7PG1 to a commercially available silver (Ag) paste (conductor paste SOLAMET PV1505 manufactured by Du Pont); that the heat treatment temperature was changed to 800° C.; that the solder was changed to that of Sample Example 8; and that the bonding temperature was changed to 230° C.

### Comparative Example 22

A photovoltaic cell element was prepared in the same manner as in Example 22 except that the solder bonding temperature was changed to 230° C.

### Comparative Example 23

A photovoltaic cell element was prepared in the same manner as in Example 22 except that the solder bonding temperature was changed to 180° C.

[Evaluation of Power Generation Performance as Photovoltaic Cell]

The thus prepared photovoltaic cell elements were evaluated using a solar simulator (WXS-1555-10 manufactured by WACOM Electric CO., Ltd.) and a current-voltage (I-V) measuring apparatus (I-V curve tracer MP-160 manufactured by EKO Instruments Co., Ltd.) in combination.

As the power generation performance of the photovoltaic cells, Eff (conversion efficiency) and FF (fill factor) as well as Voc (open-circuit voltage) and Jsc (short-circuit current) were measured in accordance with JIS-C-8912, JIS-C-8913 and JIS-C-8914, respectively. The thus obtained measured values were converted into relative values taking the measured values of Comparative Example 21 as 100.0. Table 18 shows the values.

It is noted here that, in Comparative Examples 22 and 23, since the solder could not be bonded to the output extraction electrode and the tab wire, thus, could not be connected, these photovoltaic cell elements could not be evaluated.

TABLE 17

| | Electrode | | Solder | |
|---|---|---|---|---|
| | | Treatment | | Bonding |
| | | Temperature | Type | Temperature |
| Example | Type | (° C.) | (composition) | (° C.) |
| Example 21 | Same as Sample Example 1 | | | 300 |
| Example 22 | Same as Sample Example 5 | | | 210 |
| Example 23 | Same as Sample Example 5 | | | 190 |
| Example 24 | Same as Sample Example 6 | | | 185 |
| Example 25 | Same as Sample Example 11 | | | 210 |
| Example 26 | Same as Sample Example 11 | | | 200 |
| Comparative | Ag | 800 | Same as Sample | 230 |
| Example 21 | | | Example 8 | |

| | | |
|---|---|---|
| Comparative | Same as Sample Example 5 | 230 |
| Example 22 | | |
| Comparative | Same as Sample Example 5 | 180 |
| Example 23 | | |

TABLE 18

| | Power Generation Performance as Photovoltaic Cell | | | |
|---|---|---|---|---|
| | Eff | | Voc | Jsc |
| | (relative | FF | (relative | (relative |
| | value) | (relative | value) | value) |
| | Conversion | value) | Open-Circuit | Short-Circuit |
| Example | Efficiency | Fill Factor | Voltage | Current |
| Example 21 | 98.5 | 98.2 | 96.8 | 97.6 |
| Example 22 | 99.7 | 97.8 | 100.2 | 101.0 |
| Example 23 | 99.8 | 99.7 | 98.8 | 100.4 |
| Example 24 | 103.0 | 101.6 | 101.6 | 103.3 |
| Example 25 | 99.8 | 99.7 | 98.3 | 102.3 |
| Example 26 | 99.7 | 98.6 | 99.5 | 100.5 |
| Comparative | 100.0 | 100.0 | 100.0 | 100.0 |
| Example 21 | | | | |

| | |
|---|---|
| Comparative | Bonding was not attained, |
| Example 22 | so that evaluation could not be performed. |
| Comparative | Bonding was not attained, |
| Example 23 | so that evaluation could not be performed. |

The performances of the photovoltaic cell elements prepared in Examples 21 to 26 were comparable or superior as compared to that of the photovoltaic cell element prepared in Comparative Example 21.

### Example 27

Using the electrode paste composition Cu7PG1 obtained in the above, a photovoltaic cell element 27 having the structure shown in FIGS. 5A and 5B were prepared in the same manner as in Example 21.

When the thus obtained photovoltaic cell element was evaluated in the same manner as described in the above, the photovoltaic cell element was found to exhibit excellent characteristics in the same manner as described in the above.

The foregoing description of the embodiments of the present invention has been provided for the purposes of illustration and description. It is not intended to be exhaustive or to limit the present invention to the precise forms disclosed. Obviously, many modifications and variations will be apparent to practitioners skilled in the art. The embodiments were chosen and described in order to best explain the principles of the present invention and its practical applications, thereby enabling others skilled in the art to understand the present invention for various embodiments and with the various modifications as are suited to the particular use contemplated. It is intended that the scope of the present invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. A solder bonded body, comprising:
an oxide body to be bonded having an oxide layer on a surface thereof and
a solder layer bonded to the oxide layer, the solder layer having a zinc content of 1% by mass or less and being formed from an alloy containing at least two metals selected from the group consisting of tin, copper, silver, bismuth, lead, aluminum, titanium and silicon and having a melting point of lower than 450° C.

2. The solder bonded body according to claim 1, wherein the solder layer has an indium content of 1% by mass or less.

3. The solder bonded body according to claim 1, wherein the solder layer is bonded at a temperature of from the solidus temperature to the liquidus temperature thereof.

4. The solder bonded body according to claim 3, wherein the solder layer has a difference between the liquidus temperature and the solidus temperature of 2° C. or more.

5. The solder bonded body according to claim 1, wherein the oxide body to be bonded is at least one selected from the group consisting of oxides, metals covered with an oxide layer, glasses and oxide ceramics.

6. A method of producing the solder bonded body according to claim 1, the method comprising:
contacting with a solder layer to an oxide body to be bonded by bringing a solder material, which has a zinc content of 1% by mass or less and is formed from an alloy containing at least two metals selected from the group consisting of tin, copper, silver, bismuth, lead, aluminum, titanium and silicon and having a melting point of lower than 450° C.; and
subjecting the resultant to a heat treatment at a temperature of from the solidus temperature to the liquidus temperature of the solder material.

7. The method of producing a solder bonded body according to claim 6, wherein the solder material has an indium content of 1% by mass or less.

8. The method of producing a solder bonded body according to claim 6, wherein the solder material has a difference between the liquidus temperature and the solidus temperature of 2° C. or more.

9. The method of producing a solder bonded body according to claim 6, wherein the temperature of from the solidus temperature to the liquidus temperature is a temperature at which a ratio of liquid phase in the solder layer as a whole is from 30% by mass to less than 100% by mass.

10. The method of producing a solder bonded body according to claim 6, wherein the oxide body to be bonded is at least one selected from the group consisting of oxides, metals covered with an oxide layer, glasses and oxide ceramics.

11. The method of producing a solder bonded body according to claim 6, not comprising an ultrasonic bonding process.

12. An element, comprising:
a semiconductor substrate;
an electrode provided on the semiconductor substrate, the electrode containing phosphorus and copper and having an oxide layer on a surface thereof; and
a solder layer provided on the oxide layer, the solder layer being bonded at a temperature of from a solidus temperature to a liquidus temperature of the solder layer.

13. The element according to claim 12, wherein the temperature of from the solidus temperature to the liquidus temperature is from higher than the solidus temperature to lower than the liquidus temperature.

14. The element according to claim 12, wherein the temperature of from the solidus temperature to the liquidus temperature is a temperature at which a ratio of liquid phase in the solder layer as a whole is from 30% by mass to less than 100% by mass.

15. The element according to claim 12, wherein the electrode further comprises tin.

16. An element, comprising
a semiconductor substrate;
an electrode provided on the semiconductor substrate, the electrode containing phosphorus and copper and having an oxide layer on a surface thereof; and
a solder layer provided on said oxide layer, the solder layer having a difference between a liquidus temperature and a solidus temperature of 2° C. or more.

17. An element, comprising
a semiconductor substrate;
an electrode provided on the semiconductor substrate, the electrode containing phosphorus and copper and having an oxide layer on a surface thereof; and
a solder layer bonded to the oxide layer.

18. The element according to claim 12, being an element for a photovoltaic cell, wherein the semiconductor substrate has an impurity diffusion layer to which it is pn-joined, and the electrode is provided on the impurity diffusion layer.

19. A photovoltaic cell, comprising:
the element for a photovoltaic cell according to claim 18; and
a wiring member, which is provided on the oxide layer of the surface of the electrode in the element for a photovoltaic cell, and which is connected with the solder layer.

20. A method producing an element, the method comprising:
preparing a substrate which has a semiconductor substrate and an electrode provided on the semiconductor substrate, the electrode containing phosphorus and copper and having an oxide layer on a surface thereof; and
bonding a solder layer on the oxide layer by performing a heat treatment at a temperature of from a solidus temperature to a liquidus temperature of the solder layer.

21. The method of producing an element according to claim 20, the element being an element for a photovoltaic cell, wherein the semiconductor substrate has an impurity diffusion layer to which it is pn-joined, and the electrode is provided on the impurity diffusion layer.

22. A method of producing a photovoltaic cell, the method comprising:
preparing a photovoltaic cell substrate comprising a semiconductor substrate having an impurity diffusion layer to which it is pn-joined and an electrode provided on the impurity diffusion layer, the electrode containing phosphorus and copper and having an oxide layer on a surface thereof and
bonding a wiring member on the oxide layer with a solder layer by subjecting the solder layer to a heat treatment at a temperature of from a solidus temperature to a liquidus temperature thereof.
